(19) United States
(12) Patent Application Publication
(10) Pub. No.: US 2026/0239766 A1
(43) Pub. Date: Aug. 13, 2026

(54) IMAGING INTEGRATED CIRCUIT DEVICE AND METHOD OF MANUFACTURING THE SAME

(71) Applicant: Taiwan Semiconductor Manufacturing Company, Ltd., Hsinchu (TW)

(72) Inventors: Cheng Ying Ho, Minxiong Township (TW); Kai-Chun Hsu, Tainan City (TW); Wen-De Wang, Minsyong Township (TW); Jen-Cheng Liu, Hsin-Chu City (TW)

(21) Appl. No.: 19/049,255

(22) Filed: Feb. 10, 2025

(51) Int. Cl. H10F 39/00; H01L 23/00; H01L 23/522

(52) U.S. Cl. CPC H10F 39/811; H10F 39/018; H10F 39/809; H10W 20/496; H10W 80/312; H10W 80/327; H10W 90/792

(57) ABSTRACT

Some embodiments relate to an integrated circuit (IC) device including a photodetector, a floating diffusion region, a transfer gate structure configured to electrically couple the photodetector to the floating diffusion region, first and second capacitor structures, and first and second transistor structures. The second transistor structure is configured to electrically couple the second capacitor structure to the floating diffusion region. The first transistor structure is configured to electrically couple the first capacitor structure to the second capacitor structure in parallel. One of the first capacitor structure or the second capacitor structure includes at least a portion of a first conductive element and a portion of a second conductive element laterally separated from each other. The other one of the first capacitor structure or the second capacitor structure includes at least a portion of a first conductive element and a portion of a second conductive element vertically separated from each other.

### BACKGROUND

While innovation in integrated circuit (IC) design is often directed to reducing the size and increasing the speed of transistors, such as for various types of digital electronics, the incorporation of analog components, such as capacitors, within IC devices remains an important aspect of IC design. For example, complementary metal-oxide-semiconductor (CMOS) image sensor (CIS) devices may incorporate capacitors for storage of electrical charge collected in corresponding photosensitive components.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, and 1C illustrate schematic views of some embodiments of a pixel circuit employing a multi-capacitor lateral overflow integration capacitor (LOFIC) arrangement, according to the present disclosure.

FIGS. 2A through 2D illustrate graphs of a pixel signal-to-noise ratio (SNR) versus light exposure of some embodiments of an IC imaging device including a pixel circuit employing a multi-capacitor LOFIC arrangement, according to the present disclosure.

FIG. 3 illustrates a cross-sectional view of some embodiments of an IC imaging device including a pixel circuit employing a multi-capacitor LOFIC arrangement, according to the present disclosure.

FIGS. 4A and 4B illustrate cross-sectional and plan views, respectively, of some additional embodiments of an IC imaging device including a pixel circuit employing a multi-capacitor LOFIC arrangement, according to the present disclosure.

FIGS. 5 through 16 illustrate cross-sectional views of more embodiments of an IC imaging device including a pixel circuit employing a multi-capacitor LOFIC arrangement, according to the present disclosure.

FIGS. 17A through 17V illustrate cross-sectional views of some embodiments of an IC imaging device associated with FIG. 16, including a pixel circuit employing a multi-capacitor LOFIC arrangement in various stages of manufacture, according to the present disclosure.

FIGS. 18 and 19 illustrate methodologies of forming an IC imaging device including a pixel circuit employing a multi-capacitor LOFIC arrangement, in accordance with some embodiments of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some complementary metal-oxide-semiconductor (CMOS) image sensor (CIS) integrated circuit (IC) designs, a capacitor may be employed as a lateral overflow integration capacitor (LOFIC) to selectively couple the capacitor with a floating diffusion region of a pixel circuit to provide a dual conversion gain arrangement. Accordingly, the CIS may employ a high conversion gain to provide accurate sensing in low light conditions, and may use a low conversion gain to prevent image overexposure or “blooming” in strong light conditions. However, in more intermediate light conditions, the use of a dual conversion gain may introduce an undesirable reduction in signal-to-noise ratio experienced by the pixel, particularly when the ratio of the high conversion gain value to the low conversion gain value is significant.

To address this issue, the present disclosure provides some embodiments of an IC device including a pixel circuit that employs a multi-capacitor LOFIC arrangement to provide three or more conversion gain modes. In some embodiments, an IC device may include a first IC die and a second IC die. The first IC die may include a photodetector, a floating diffusion region, and a transfer gate structure configured to electrically couple the photodetector to the floating diffusion region. The second IC die may be coupled to the first IC die and include a plurality of capacitor structures selectively coupled in a lateral overflow integration capacitor (LOFIC) arrangement with the floating diffusion region. In some embodiments, the plurality of capacitor structures may include at least two of a three-dimensional metal-insulator-metal (3DMIM) capacitor structure, a two-dimensional metal-insulator-metal (2DMIM) capacitor structure, and a metal-oxide-metal (MOM) capacitor structure. In other embodiments, rather than two (or more) IC dies including the various structures, a single IC die may include a pixel circuit with the photodetector, floating diffusion region, and transfer gate structure, as well as the multi-capacitor LOFIC arrangement.

Thus, in some embodiments, in providing three or more conversion gain modes by including at least two different capacitors of different types, the ratio of the values of any two adjacent conversion gain modes may be reduced in comparison to the dual conversion gain mode, resulting in an associated reduction in the potential drop in signal-to-noise ratio. Accordingly, such an IC imaging device may provide an expanded dynamic range for a pixel while providing more accurate imaging data. Further, by employing a different capacitor type for each capacitor in the LOFIC arrangement, a corresponding variety of capacitor values may be provided, thus facilitating a series of conversion gain modes that further support a desirable signal-to-noise ratio when transitioning between modes. Additionally, in some embodiments, as described in greater detail below, multiple capacitors of different types may be disposed at corresponding diverse locations (e.g., vertically and/or laterally) within the IC image device, thus potentially resulting in more efficient use of the volume available within the device for the LOFIC arrangement.

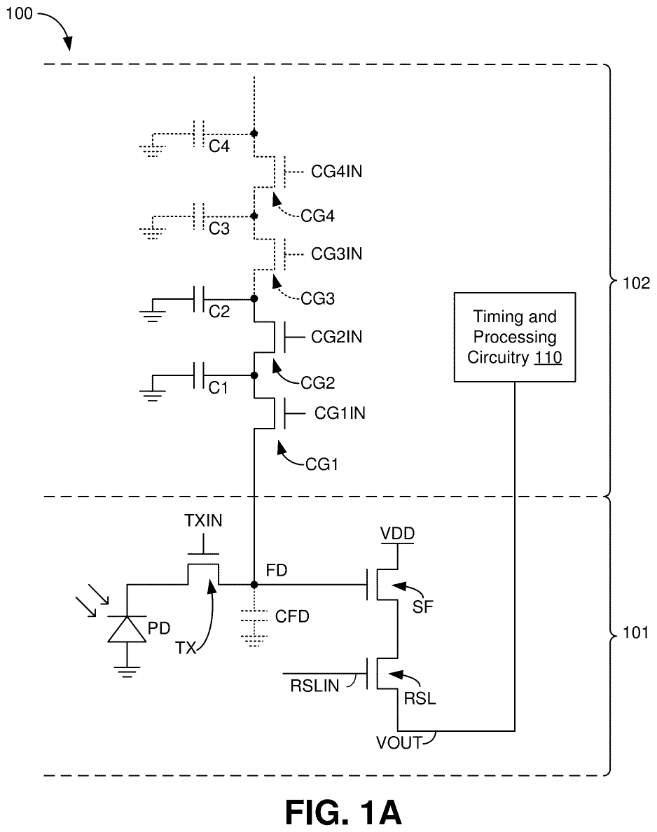

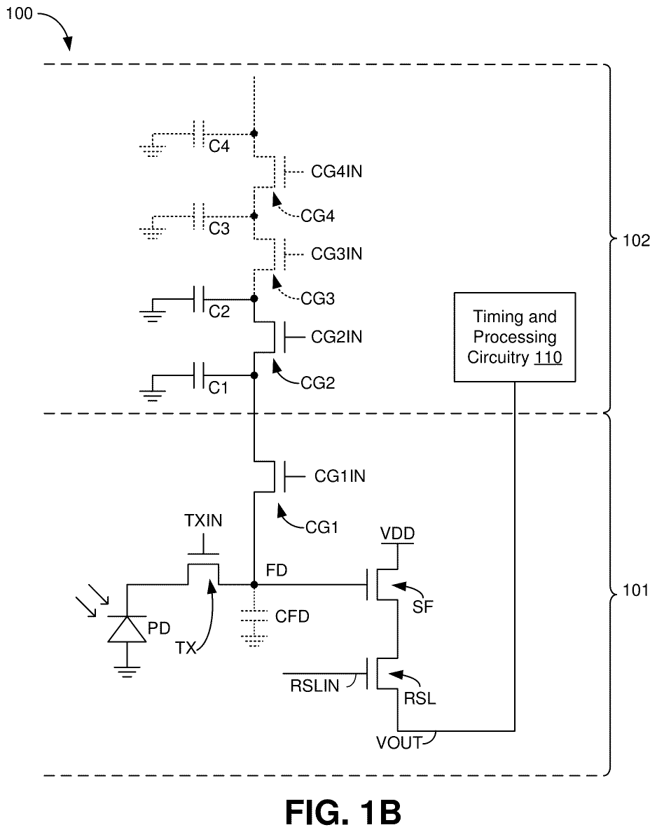

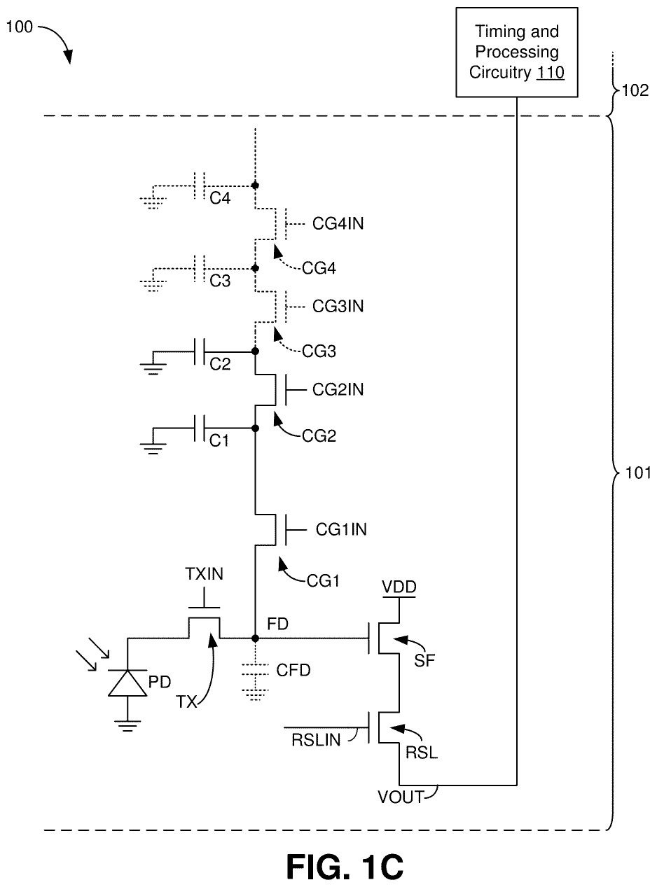

FIGS. 1A, 1B, and 1C illustrate schematic views of some embodiments of an IC device 100 employing a multi-capacitor LOFIC arrangement, according to the present disclosure. While IC device 100 may include multiple (e.g., hundreds, thousands, etc.) of pixel circuits for corresponding pixels, the embodiments presented below focus on a single pixel and associated circuitry to simplify the following discussion.

As depicted in FIGS. 1A, 1B, and 1C, IC imaging device 100 includes at least a first IC die (or wafer) 101 and a second IC die (or wafer) 102. In some embodiments, first IC die 101 may include a photodetector PD for a pixel implemented in IC imaging device 100, as well as some of the circuitry closely coupled with photodetector PD, such as a transfer transistor TX, a floating diffusion region FD, and so on. In some embodiments, second IC die 102 may include other circuitry (e.g., in addition to the circuitry provided in first IC die 101), such as capacitors for charge storage from floating diffusion region FD, as well as circuitry that facilitates the generation of digital data representing the amount of light received by the photodetector during sequential time periods. While only two IC dies 101 and 102 are depicted in FIGS. 1A and 1B, one or more additional dies may be included in IC imaging device 100 in other embodiments. Moreover, while only a single photodetector PD and associated pixel circuit are depicted in FIGS. 1A, 1B, and 1C, many such photodetectors PD and corresponding pixel circuits may be included in other embodiments.

More specifically, first IC die 101 of IC device 100 may include a photodetector PD (e.g., a photodiode, such as a PN diode) that has an anode coupled to a reference voltage (e.g., ground). Transfer transistor TX (e.g., a transistor with a transfer input signal TXIN driving a gate connection of transfer transistor TX) may have a first source-drain connection electrically coupled to a cathode of photodetector PD, as well as a second source-drain connection electrically coupled to region FD. Also, as depicted in FIGS. 1A, 1B, and 1C, a capacitor CFD (e.g., an inherent capacitance) may be associated with region FD.

Additionally, a gate connection of a source follower transistor SF may be driven by region FD. Source follower transistor SF may have a first source-drain connection connected to a reference voltage (e.g., supply voltage VDD) and a second source-drain connection connected to a first source-drain connection of a row select transistor RSL. A gate connection of transistor RSL may be driven by a row select input RSLIN (e.g., originating from timing and processing circuitry 110 of second IC die 102). Transistor RSL may also have a second source-drain connection that provides a voltage output VOUT representing a charge associated with photodetector PD at region FD that is provided to timing and processing circuitry 110.

In addition to timing and processing circuitry 110, second IC die 102 may include a plurality of capacitors C1 and C2 (and possibly C3, C4, and so on) that are coupled with region FD in a LOFIC arrangement by way of a plurality of configuration gain transistors CG1 and CG2 (and possibly additional transistors CG3, CG4, and so on). For example, in some embodiments described below, two such capacitors C1 and C2 and corresponding transistors CG1 and CG2 are included. In other embodiments, one additional capacitor C3 and associated transistor CG3 may be provided. In yet other embodiments, two additional capacitors C3 and C4 and corresponding transistors CG3 and CG4 are provided. Additional embodiments employing greater numbers of capacitors and configuration gain transistors are also possible.

As illustrated in FIGS. 1A, 1B, and 1C, each capacitor C1 through C4 may each have a first connection coupled to a reference voltage (e.g., ground) and a second connection coupled to a source-drain connection of corresponding transistor CG1 through CG4. Each transistor CG1, CG2, CG3, and CG4 may also have a gate connection driven by a configuration gain input CG1IN, CG2IN, CG3IN, and CG4IN, respectively. Moreover, transistors CG1 through CG4 may be arranged in series by way of their source-drain connections, as shown in FIGS. 1A, 1B, and 1C.

Accordingly, in some embodiments, when operated according to a multiple-conversion-gain system using the LOFIC arrangement of capacitors C1, C2, and so on, conversion gain inputs CG1IN, CG2IN, and so on may be controlled to initially provide a high conversion gain (HCG) mode (e.g., when all transistors CG1, CG2, and so on are OFF), a low conversion gain (LCG) mode (e.g., when all transistors CG1, CG2, and so on are ON), and one or more moderate conversion gain (MCG1, MCG2, and so forth) modes (e.g., when one or more transistors CG1, CG2, and so on are ON and the remaining transistors are OFF).

More specifically, as described more fully below, when only two transistors C1 and C2 and associated transistors CG1 and CG2 are present, HCG mode is provided when both transistors CG1 and CG2 are OFF, thus isolating capacitors C1 and C2 from capacitor CFD of region FD. Further, MCG1 mode is provided when transistor CG1 in ON and transistor CG2 is OFF, thus coupling capacitors C1 and CFD, but not capacitor C2, in parallel. Finally, HCG mode is provided when transistors CG1 and CG2 are ON, thus coupling capacitors C1, C2, and CFD in parallel.

In some embodiments, when three transistors C1, C2, and C3 and associated transistors CG1, CG2, and CG3 are present, HCG mode is provided when transistors CG1, CG2, and CG3 are OFF, thus isolating capacitors C1, C2, and C3 from capacitor CFD of region FD. Further, MCG1 mode is provided when transistor CG1 is ON and transistors CG2 and CG3 are OFF, thus coupling capacitors C1 and CFD, but not capacitors C2 and C3, in parallel. MCG2 mode is provided when transistors CG1 and CG2 are ON and transistor CG3 is OFF, thus coupling capacitors C1, C2, and CFD, but not capacitor C3, in parallel. Finally, LCG mode is provided when transistors CG1, CG2, and CG3 are ON, thus coupling capacitors C1, C2, C3, and CFD in parallel.

Further, in some embodiments, when four transistors C1, C2, C3, and C4 and associated transistors CG1, CG2, CG3, and CG4 are present, HCG mode is provided when transistors CG1, CG2, CG3, and CG4 are OFF, thus isolating capacitors C1, C2, C3, and C4 from capacitor CFD of region FD. Further, MCG1 mode is provided when transistor CG1 is ON and transistors CG2, CG3, and CG4 are OFF, thus coupling capacitors C1 and CFD, but not capacitors C1, C2, and C3, in parallel. MCG2 mode is provided when transistors CG1 and CG2 are ON and transistors CG3 and CG4 are OFF, thus coupling capacitors C1, C2, and CFD, but not capacitors, C3 and C4, in parallel. MCG3 mode is provided when transistors CG1, CG2, and CG3 are ON and transistor CG4 is OFF, thus coupling capacitors C1, C2, C3, and CFD, but not capacitor C4, in parallel. Finally, LCG mode is provided when transistors CG1, CG2, CG3, and CG4 are ON, thus coupling capacitors C1, C2, C3, C4, and CFD in parallel.

In some embodiments, the resulting voltage potentials at region FD in the various conversion gain modes may then be provided to timing and processing circuitry 110 by way of transistors SF and RSL, as described above. Also, in some embodiments, the second source-drain connection of the last transistor in the series of transistors CG1, CG2, and so on may be coupled to other circuitry, such as a reset transistor (not explicitly shown in FIG. 1) that may reset the charges and voltages of the pixel to begin another charge accumulation cycle at photodetector PD. For example, a reset transistor may have a first source-drain connection coupled with the end of the last or farthest capacitor (e.g., capacitor C4) of the LOFIC arrangement and its associated transistor (e.g., transistor CG4) and a second source-drain connection coupled to a voltage reference (e.g., VDD or ground). Other similar additions or changes to the circuitry of FIGS. 1A, 1B, and 1C are also possible in other embodiments.

FIG. 1B depicts the same circuitry as that of FIG. 1A. However, in contrast to FIG. 1A, in which transistor CG1 is included in second IC die 102, in FIG. 1B, transistor CG1 is disposed in first IC die 101. Other allotments of the various circuit elements of IC device 100 among first IC die 101 and second IC die 102 are also possible in other embodiments. Further, as illustrated in FIG. 1C, in some embodiments, some or all of the individual components depicted in FIGS. 1A and 1B (e.g., photodetector PD, transistors TX, SF, RSL, CG1 through CG4, capacitors C1 through C4) may be disposed within a single IC die (e.g., first IC die 101).

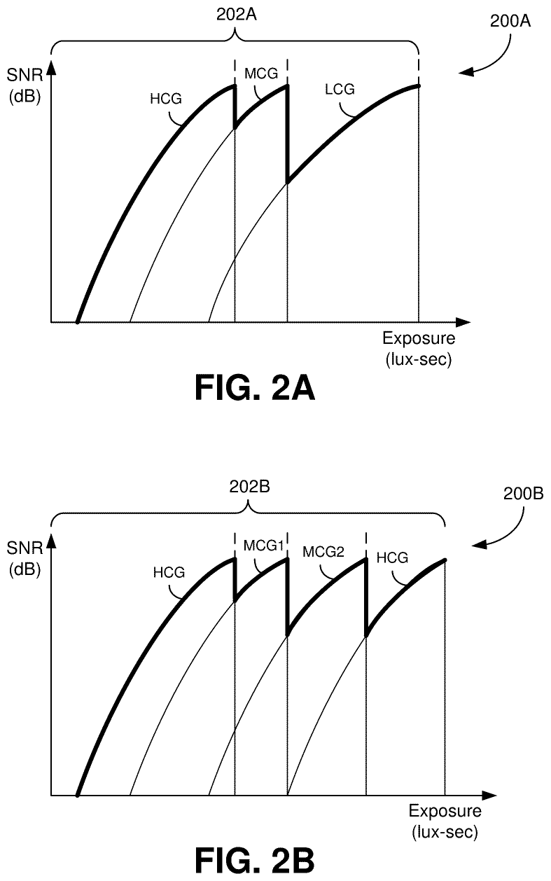

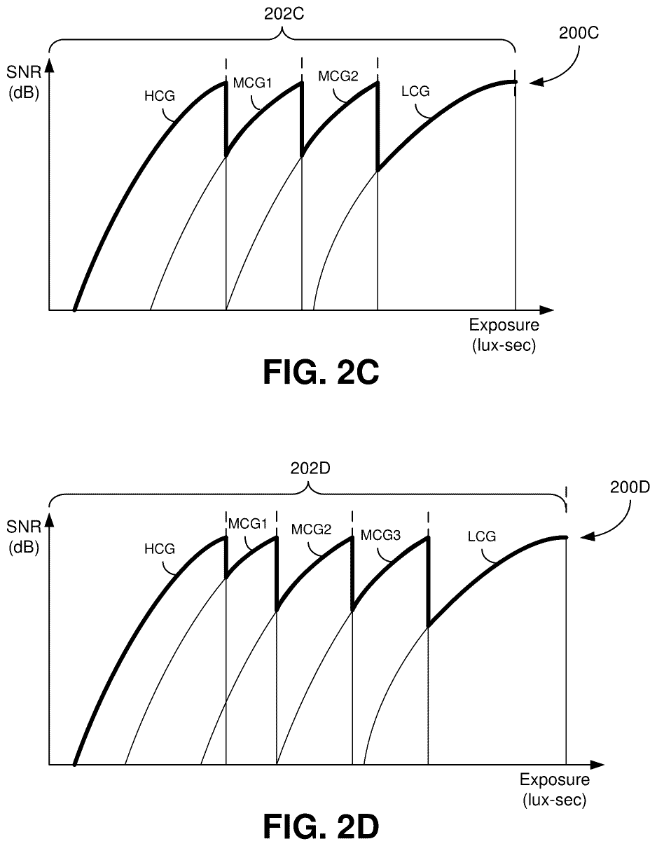

FIGS. 2A through 2D illustrate graphs 200A through 200D, respectively, of a pixel signal-to-noise ratio (SNR) (e.g., in decibels (dB)) versus light exposure (e.g., in lux-seconds (lux-sec)) of some embodiments of an IC imaging device 100 including a pixel circuit employing a multi-capacitor LOFIC arrangement, according to the present disclosure. In each of FIGS. 2A through 2D, the bold line denotes the resulting overall SNR associated with each conversion gain mode (e.g., HCG mode, one or more MCG modes (e.g., MCG1, MCG2, and so on), and LCG mode) resulting from the use of a multi-capacitor LOFIC arrangement. Moreover, the thinner lines denote the SNR associated with each individual conversion gain mode. Accordingly, the use of a multi-capacitor LOFIC arrangement may limit potential reductions in SNR over the entire exposure range of IC device 100, thus providing an accurate image signal over a large exposure range.

More specifically, in FIG. 2A, graph 200A indicates that two capacitors (e.g., capacitors C1 and C2 of FIGS. 1A and 1B) yield three conversion gain modes HCG, MCG, and LCG, as discussed above, providing an exposure range 202A over which a reduction in SNR is limited. Similarly in FIGS. 2B and 2C, graphs 200B and 200C, respectively, indicate that three capacitors (e.g., capacitors C1, C2, and C3 of FIGS. 1A and 1B) yield four conversion gain modes HCG, MCG1, MCG2, and LCG. Further, graphs 200B and 200C provide corresponding exposure ranges 202B and 202C, respectively. FIG. 2D illustrates graph 200D that indicates that four capacitors (e.g., capacitors C1, C2, C3, and C4 of FIGS. 1A and 1B) generate five conversion gain modes HCG, MCG1, MCG2, MCG3, and LCG over an exposure range 202D.

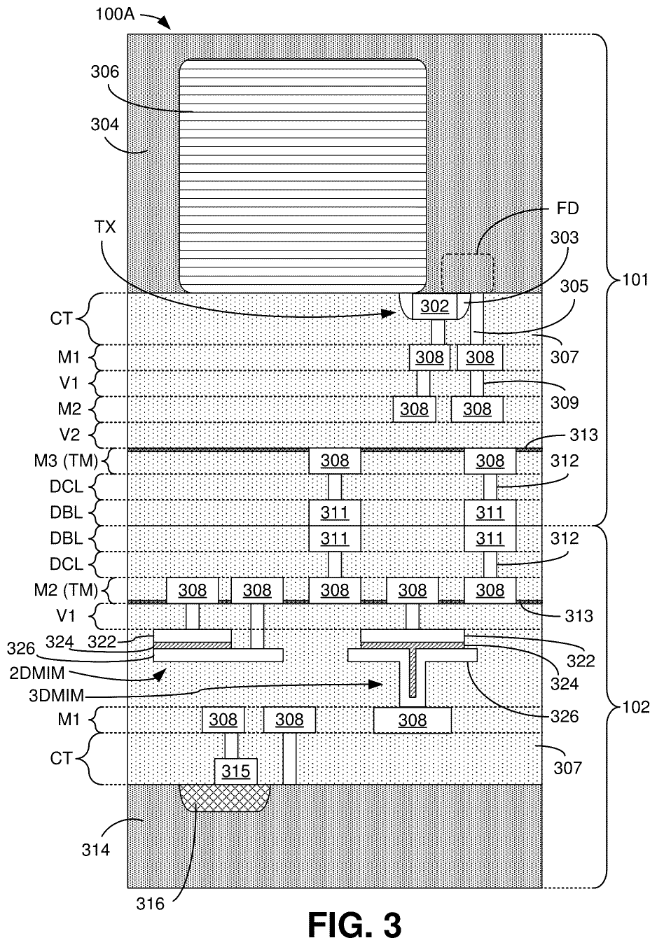

FIG. 3 illustrates a cross-sectional view of some embodiments of an IC imaging device 100A including a pixel circuit employing a multi-capacitor LOFIC arrangement, according to the present disclosure. In some embodiments, as depicted in FIG. 3, each pixel circuit may include two capacitors: a three-dimensional metal-insulator-metal capacitor structure 3DMIM and a two-dimensional metal-insulator-metal capacitor structure 2DMIM in a LOFIC arrangement. Further, in some embodiments, capacitor structure 2DMIM may serve as capacitor C1 of FIGS. 1A and 1B, and capacitor structure 3DMIM may serve as capacitor C2 of FIGS. 1A and 1B, although the alternative association among capacitor structures 2DMIM, 3DMIM, C1, and C2 is also possible.

Beginning with first IC die 101, which is shown inverted relative to an orientation in which first IC die 101 may be fabricated, a semiconductor substrate 304 (e.g., silicon or another semiconductor material) may include a photosensitive region 306 to serve as a photodetector PD (e.g., PN photodiodes or “pinned” photodiodes) in conjunction with the surrounding area of substrate 304. In some embodiments, substrate 304 may be p-doped silicon, and photosensitive region 306 may be doped with ions to create n-doped regions. Near photosensitive region 306 may be floating diffusion region FD. Photosensitive region 306 may be configured to receive light through an upper side of substrate 304 (e.g., the side of substrate 304 opposite second IC die 102) by way of a lens and an optical filter (e.g., a color filter, a bandwidth filter, or the like) (not explicitly shown in FIG. 3).

One or more dielectric layers for dielectric structure 307, within which multiple conductive structures 308 and corresponding vias 309 may be located, may be disposed over substrate 304. In some embodiments, a gate structure 302 and associated sidewall spacer 303 may be formed on semiconductor substrate 304 adjacent photosensitive region 306. Dielectric structure 307 may include one or more dielectric materials, including, but not limited to, silicon oxide (SiOx) (e.g., silicon oxide (SiO2)), silicon nitride (SiN), silicon carbide (SiC), carbon-doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like. Conductive structures 308 and conductive vias 309 may include copper (Cu) or another metal, metal alloy, or other conductive material. In some embodiments, gate structure 302 may be made of polycrystalline silicon (poly-Si) or another conductive material. Also, in some embodiments, gate structure 302 may be controlled as a transfer gate of transfer transistor TX to transfer charge collected in photodetector PD by way of floating diffusion region FD over some period of time to a measurement node by way of a measurement contact 305 adjacent gate structure 302.

As illustrated in FIG. 3, gate structure 302, sidewall spacer 303, and measurement contact 305 may be disposed within a contact layer CT. Further, multiple conductive (e.g., metal) layers M1, M2, and M3 and intervening via layers V1 and V2 may be disposed over contact layer CT to facilitate electrical connections between various components of first IC die 101, such as between measurement contact 305 (e.g., serving as the second drain-source connection of transfer transistor TX) and the gate connection of source follower transistor SF (not explicitly shown in FIG. 3). Further, the uppermost metal layer M3 may also be viewed as the top metal layer TM in some embodiments. In other embodiments, greater or fewer numbers of conductive layers and via layers may be used in both first IC die 101 and second IC die 102.

Also, in some embodiments, one or more etch stop layers 313 may be included between layers of dielectric structure 307 in both first IC die 101 and second IC die 102. In some embodiments, etch stop layer 313 may include one or more of silicon nitride (SiN), silicon carbide (SiC), silicon carbonitride (SiCN), or another dielectric material.

In some embodiments, disposed on top metal layer TM in first IC die 101 may be a bond contact layer DCL and a bond layer DBL. In some embodiments, bond layer DBL may include conductive structures 311, and bond contact layer DCL may include conductive contacts 312 that couple conductive structures 311, respectively, to other conductive structures 308 of top metal layer TM. In some embodiments, conductive structures 311 may electrically couple various elements of first IC die 101 (e.g., floating diffusion region FD, voltage output VOUT, and so on) to various components of second IC die 102 (e.g., conversion gain transistor CG1, timing and processing circuitry 110, and so on).

Proceeding with second IC die 102, a semiconductor substrate 314 (e.g., silicon or another semiconductor material) may include doped regions 316 that may be operated as source-drain regions for transistors that provide functionality (e.g., timing and processing circuitry 110, conversion gain transistors CG1, CG2, and so) related to IC imaging device 100A. One or more dielectric layers for dielectric structure 307, within which multiple conductive structures 308 are located, may be disposed over substrate 314. In FIG. 3, second IC die 102 is disposed in an inverse orientation relative to first IC die 101 to facilitate bonding therebetween. In some embodiments, conductive structures may include polycrystalline silicon (poly-Si) structures 315 or other conductive structures that couple doped regions 316 to other conductive structures. In some embodiments, poly-Si structures 315 may be disposed within a contact layer CT. Further, conductive (e.g., metal) layers M1 and M2, and intervening via layer V1, may be disposed over contact layer CT to facilitate electrical connections between various components of second IC die 102. The uppermost metal layer M2 may also be viewed as top metal layer TM of second IC die 102 in some embodiments.

In some embodiments, as in the case of first IC die 101, disposed over top metal layer TM of second IC die 102 may be a bond contact layer DCL and a bond layer DBL. In some embodiments, bond layer DBL may include conductive structures 311, and bond contact layer DCL may include conductive contacts 312 that couple conductive structures 311 to other conductive structures 308 of top metal layer TM.

Further, in some embodiments, bond layer DBL of first IC die 101 and bond layer DBL of second IC die 102 may be bonded together (e.g., by way of heat-based bonding) such that conductive structures 311 of first IC die 101 and second IC die 102 make contact to provide one or more electrical connections between first IC die 101 and second IC die 102.

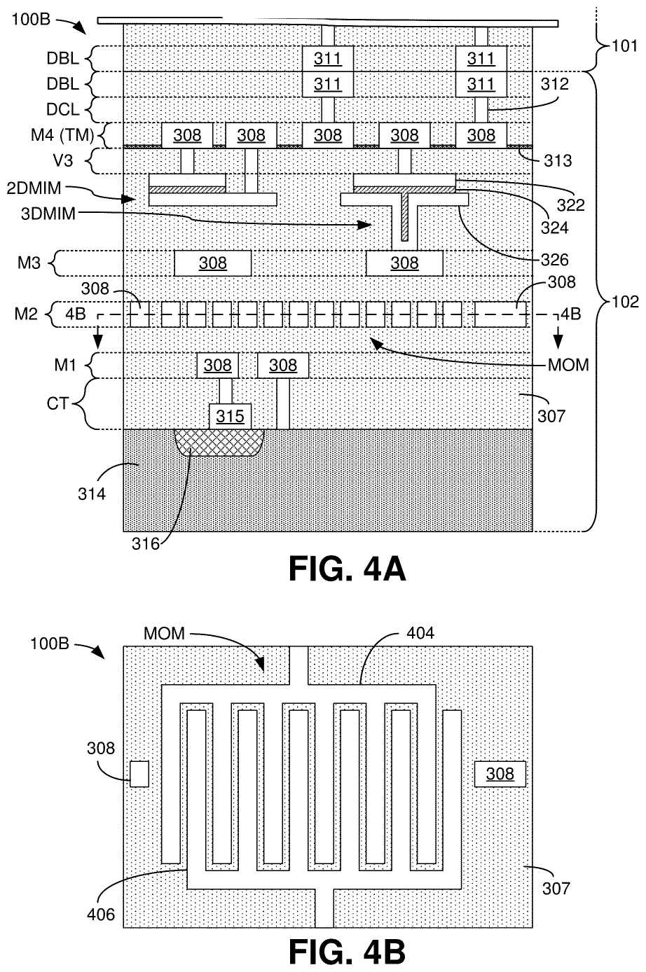

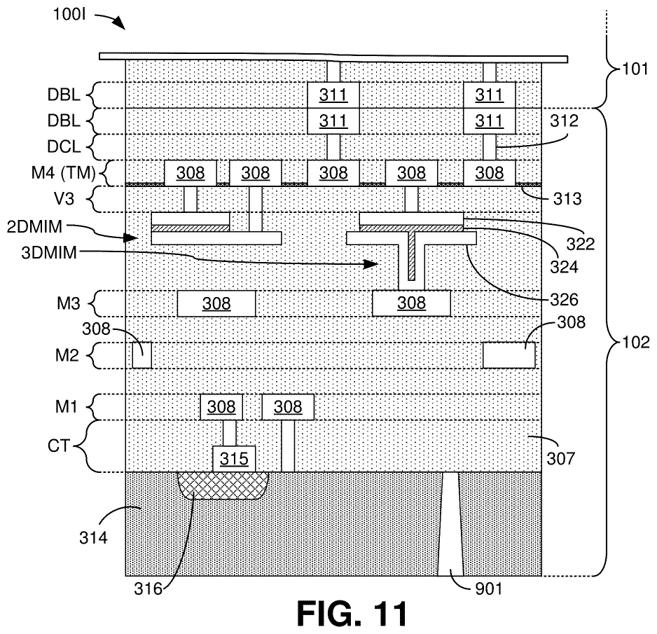

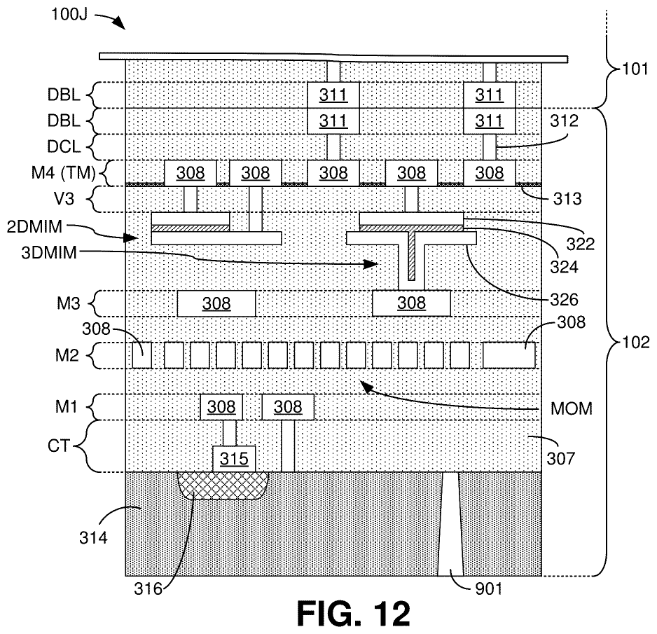

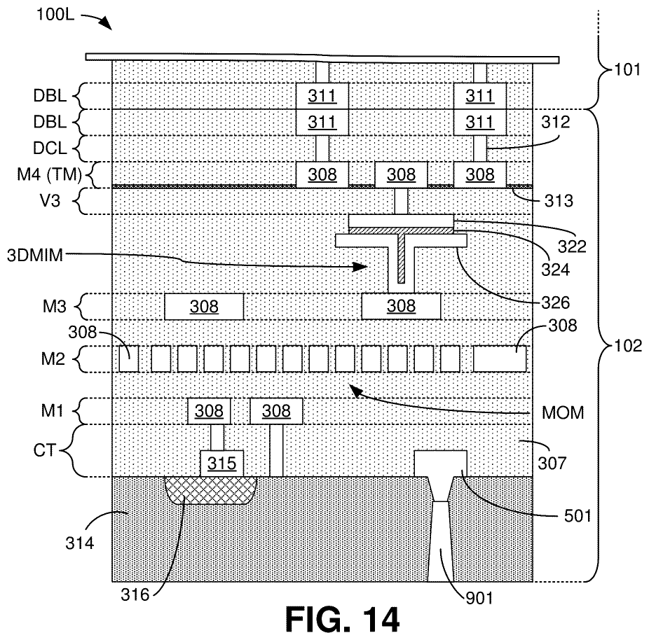

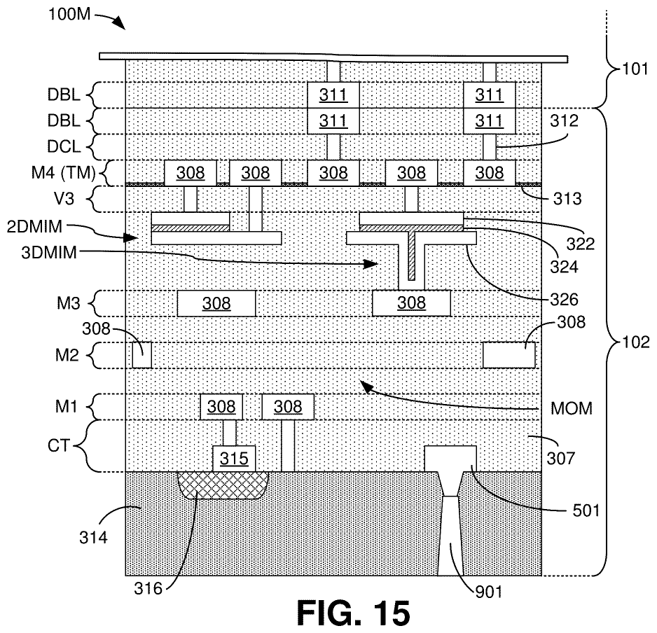

Also, as shown in FIG. 3, as well as in FIGS. 4A, 4B, and 5 through 16, two or more capacitors (e.g., capacitors C1, C2, and so on) configured in a LOFIC arrangement, in conjunction with two or more conversion gain transistors (e.g., transistors CG1, CG2, and so on, not explicitly shown in FIG. 3 and subsequent figures), may be disposed in second IC die 102. In some embodiments, one or more conductive elements of capacitors C1, C2, and so on may be coupled by way of direct connection or by one or more vias to conductive structures 308 for electrical coupling to other circuitry, such as transistors CG1, CG2, and the like.

In FIG. 3, for example, a two-dimensional metal-insulator-metal capacitor structure 2DMIM may serve as one of capacitor C1 or C2 (e.g., capacitor C1), while a three-dimensional metal-insulator-metal capacitor structure 3DMIM may serve as the other of capacitor C1 or C2 (e.g., capacitor C2). Accordingly, in a high conversion gain HCG mode, neither capacitor structure 2DMIM nor capacitor structure 3DMIM may be coupled to region FD. In a moderate conversion gain MCG mode, in some embodiments, capacitor structure 2DMIM may be coupled in parallel to floating diffusion region FD, while in a low conversion gain LCG mode, both capacitor structures 2DMIM and 3DMIM may be coupled in parallel to region FD. Consequently, the overall signal-to-noise ratio exhibited by embodiments of FIG. 3 that employ HCG mode, MCG mode, and LCG mode may resemble that depicted above in FIG. 2A.

In some embodiments, both capacitor structures 2DMIM and 3DMIM may include a first conductive element 326, a dielectric element 324 disposed on first conductive element 326, and a second conductive element 322 disposed on dielectric element 324. In the case of capacitor structure 2DMIM, first conductive element 326, dielectric element 324, and second conductive element 322 may each be a planar structure. In capacitor structure 3DMIM, at least first conductive element 326 and dielectric element 324 may have one or more portions extending toward substrate 314 of second IC die 102, thus increasing the possible capacitance of capacitor structure 3DMIM. More specifically, in some embodiments of capacitor structure 3DMIM, first conductive element 326 may line one or more trenches defined by one or more dielectric layers of dielectric structure 307. Further, dielectric element 324 may be arranged over first conductive element 326 and may include a protrusion extending vertically downward to be surrounded by a portion of first conductive element 326. Additionally, second conductive element 322 may be a planar (e.g., horizontal) structure disposed on dielectric element 324.

Consequently, in some embodiments, an upper horizontal portion of first conductive element 326 of capacitor structure 3DMIM and first conductive element 326 of capacitor structure 2DMIM may be disposed at a same vertical distance above substrate 314. Similarly, in some embodiments, an upper horizontal portion of dielectric element 324 of capacitor structure 3DMIM and dielectric element 324 of capacitor structure 2DMIM may be disposed at a same vertical distance above substrate 314. Also, in some embodiments, second conductive element 322 of capacitor structures 3DMIM and 2DMIM may be disposed at a same vertical distance above substrate 314.

In some embodiments, a capacitance of capacitor structure 2DMIM is less than a capacitance of capacitor structure 3DMIM. For example, in some embodiments, capacitor structure 2DMIM may provide a capacitance in a range of approximately 10 to 30 picofarads (pF) (e.g., approximately 20 pF), while capacitor structure 3DMIM may provide a capacitance in a range of approximately 20 to 40 pF (e.g., approximately 30 pF).

Further, at least some portion of each of first conductive element 326, dielectric element 324, and second conductive element 322 of capacitor structures 2DMIM and 3DMIM may be disposed at a same vertical distance over substrate 314, thus facilitating the concurrent fabrication of at least some portions of capacitor structures 2DMIM and 3DMIM.

With respect to both capacitor structures 2DMIM and 3DMIM, in some embodiments, first conductive element 326 and/or second conductive element 322 may include, but are not limited to, titanium nitride (TiN), an aluminum-copper (AlCu) alloy, tungsten (W), and/or another metal or metal alloy, polycrystalline silicon (poly-Si), and/or another conductive material. Further, in some embodiments, dielectric element 324 may include, but is not limited to, a high-κ dielectric material, such as hafnium silicate (HfO₆Si₂), zirconium silicate (ZrSiO₄), hafnium dioxide (HfO₂), zirconium dioxide (ZrO₂), and/or the like. In other embodiments, dielectric element 324 may include other dielectric materials that are not high-κ dielectric or insulating materials.

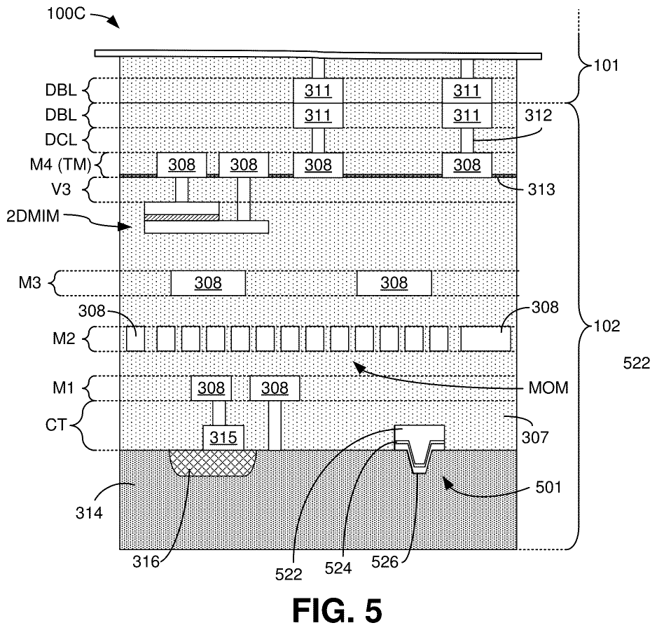

FIGS. 4A and 4B illustrate cross-sectional and plan views, respectively, of some additional embodiments of an IC imaging device 100B including a pixel circuit employing a multi-capacitor LOFIC arrangement, according to the present disclosure. In FIGS. 4A and 4B, as well as FIGS. 5 through 16, only a portion of first IC die 101 is depicted to simplify the corresponding discussions. Further, in some embodiments, other than the structures that are discussed with respect to each figure, other aspects of first IC die 101 and second IC die 102 of each figure may be the same or similar as those discussed above in conjunction with FIG. 3.

In contrast to IC device 100A of FIG. 3, in which two capacitor structures 2DMIM and 3DMIM are employed in a LOFIC configuration, IC device 100B of FIGS. 4A and 4B provides three such capacitor structures: capacitor structure 2DMIM, capacitor structure 3DMIM, and a metal-oxide-metal capacitor structure MOM. In some embodiments, as shown to best effect in FIG. 4A, capacitor structure MOM may possess a substantially planar structure within dielectric structure 307 (e.g., at or within a conductive layer (e.g., metal layer M2, as shown in FIG. 4A)). Further, capacitor structure MOM may be disposed between at least one of capacitor structure 2DMIM or capacitor structure 3DMIM and substrate 314.

In some embodiments, as shown in FIG. 4B, capacitor structure MOM may include two conductive elements 404 and 406, where each conductive element includes multiple laterally extending portions that interleave with such portions of the opposing conductive element. Further, in some embodiments, conductive elements 404 and 406 may be laterally separated by a portion of the dielectric material of dielectric structure 307. In some embodiments, conductive elements 404 and 406 may include a metal (e.g., copper (Cu)), a metal alloy, or another conductive material. Further, in some embodiments, conductive elements 404 and 406 may include the same material as other conductive structures 308 of second IC die 102.

In some embodiments, capacitor structure MOM may serve as one of capacitor C1, C2, or C3. Further, in some particular embodiments, capacitor structure MOM may serve as capacitor C1, while capacitor structure 2DMIM serves as capacitor C2 and capacitor structure 3DMIM serves as capacitor C3. Accordingly, in a high conversion gain HCG mode, none of capacitor structures MOM, 2DMIM, or 3DMIM may be coupled to region FD. In a first moderate conversion gain MCG1 mode, in some embodiments, capacitor structure MOM may be coupled in parallel to floating diffusion region FD. In a second moderate conversion gain MCG2, capacitor structures MOM and 2DMIM may be coupled in parallel to floating diffusion region FD, while in a low conversion gain LCG mode, capacitor structures MOM, 2DMIM, and 3DMIM may be coupled in parallel to region FD. Consequently, the overall signal-to-noise ratio exhibited by embodiments of IC device 100B of FIGS. 4A and 4B that employ HCG mode, MCG1 mode, MCG2 mode, and LCG mode may resemble that depicted above in FIG. 2C.

FIG. 5 illustrates a cross-sectional view of some embodiments of an IC imaging device 100C including a pixel circuit employing a multi-capacitor LOFIC arrangement, according to the present disclosure. While IC device 100C includes three capacitor structures in a LOFIC configuration, as was the case with IC device 100B of FIGS. 4A and 4B above, the three capacitor structures are capacitor structure 2DMIM, capacitor structure MOM, and a first substrate capacitor structure 501. As depicted in FIG. 5, in some embodiments, first substrate capacitor structure 501 may have a vertical transfer gate (VTG)-like shape disposed at an upper surface of, and extending downward into a trench of, substrate 314. Further, in some embodiments, capacitor structure 501 may have a MIM-like capacitor structure, with a first conductive element 526 lining the trench and extending over an upper side of substrate 314, a dielectric element 524 disposed on first conductive element 526, and a second conductive element 522 disposed on dielectric element 524 and serving as a plug element. Also, in some embodiments, the materials included in first conductive element 526, dielectric element 524, and second conductive element 522 may include those described above for first conductive element 326, dielectric element 324, and second conductive element 322 of capacitor structures 2DMIM and 3DMIM of FIG. 3, as discussed above.

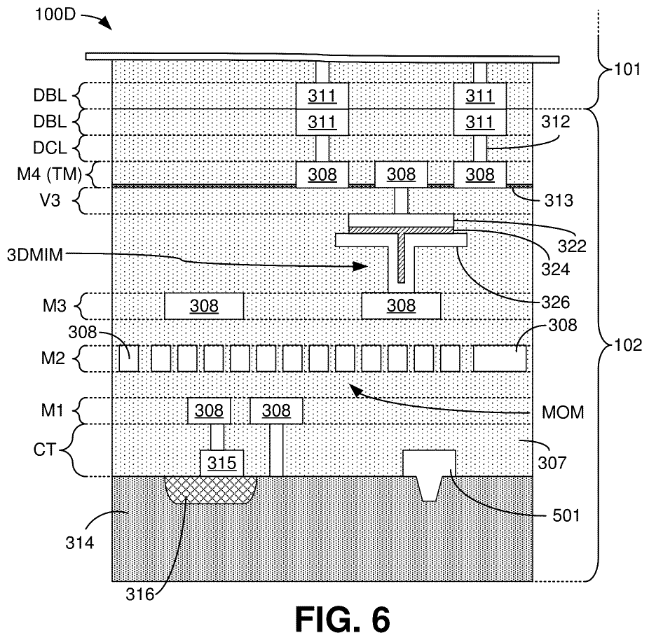

In other embodiments, as shown in FIGS. 6 through 8 and 13 through 16, capacitor structure 501 may be a single conductive structure that is primarily vertically oriented, and that at least partially extends from an upper side of substrate 314 (e.g., within dielectric structure 307) downward into substrate 314. While such a conductive structure may be employed as a gate structure for a transfer transistor (e.g., transfer transistor TX of FIGS. 1A and 1B), in embodiments associated with FIG. 5, capacitor structure 501 does not serve as a part of a transistor, but instead operates as a conductive element with an associated (e.g., inherent) capacitance that may be employed as a capacitor structure in a LOFIC arrangement. In some embodiments, capacitor structure 501 may include polycrystalline silicon (poly-Si), a metal, a metal alloy, or another conductive material. In other embodiments, either the MIM-like structure of FIG. 5 or the single conductive structure of FIGS. 6 through 8 and 13 through 16 may be used in any embodiment that employs first substrate capacitor structure 501.

In some embodiments, first substrate capacitor structure 501 may serve as one of capacitor C1, C2, or C3. In some particular embodiments, capacitor structure 501 may serve as capacitor C1, while capacitor structure MOM serves as capacitor C2 and capacitor structure 2DMIM serves as capacitor C3. Accordingly, in a high conversion gain HCG mode, none of capacitor structures 501, MOM, or 2DMIM may be coupled to region FD. In a first moderate conversion gain MCG1 mode, in some embodiments, capacitor structure 501 may be coupled in parallel to floating diffusion region FD. In a second moderate conversion gain MCG2 mode, capacitor structures 501 and MOM may be coupled in parallel to floating diffusion region FD, while in a low conversion gain LCG mode, capacitor structures 501, MOM, and 2DMIM may be coupled in parallel to region FD. Consequently, the overall signal-to-noise ratio exhibited by embodiments of IC device 100C of FIG. 5 that employ HCG mode, MCG1 mode, MCG2 mode, and LCG mode may resemble that depicted above in FIG. 2B.

FIG. 6 illustrates a cross-sectional view of some embodiments of an IC imaging device 100D including a pixel circuit employing a multi-capacitor LOFIC arrangement, according to the present disclosure. In some embodiments, IC device 100D may employ the same LOFIC arrangement involving three capacitors as that used in IC device 100C of FIG. 5, as described above, with the exception that capacitor structure 2DMIM serving as capacitor C3 is replaced with capacitor structure 3DMIM. As a result, the roles of capacitors C1, C2, and C3 of FIGS. 1A and 1B are filled by capacitor structures 501, MOM, and 3DMIM, respectively. Accordingly, the overall signal-to-noise ratio exhibited by embodiments of IC device 100D of FIG. 6 that employ HCG mode, MCG1 mode, MCG2 mode, and LCG mode may resemble that depicted above in FIG. 2B.

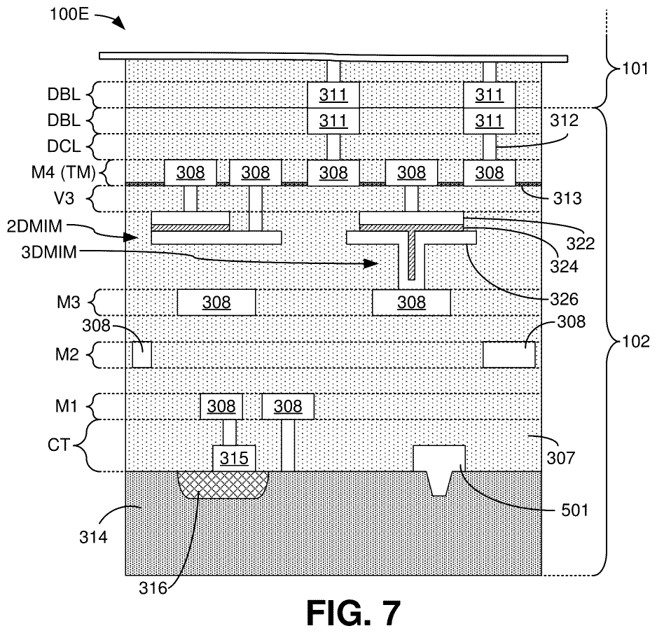

FIG. 7 illustrates a cross-sectional view of some embodiments of an IC imaging device 100E including a pixel circuit employing a multi-capacitor LOFIC arrangement, according to the present disclosure. In some embodiments, IC device 100E may employ the same LOFIC arrangement involving three capacitors as that used in IC device 100C of FIG. 5, as described above, with the exception that capacitor structures MOM and 2DMIM serving as capacitors C2 and C3 in FIG. 5 are replaced with capacitor structures 2DMIM and 3DMIM, respectively. As a result, the roles of capacitors C1, C2, and C3 of FIGS. 1A and 1B are filled by capacitor structures 501, 2DMIM, and 3DMIM, respectively. Consequently, the overall signal-to-noise ratio exhibited by embodiments of IC device 100E of FIG. 7 that employ HCG mode, MCG1 mode, MCG2 mode, and LCG mode may resemble that depicted above in FIG. 2C.

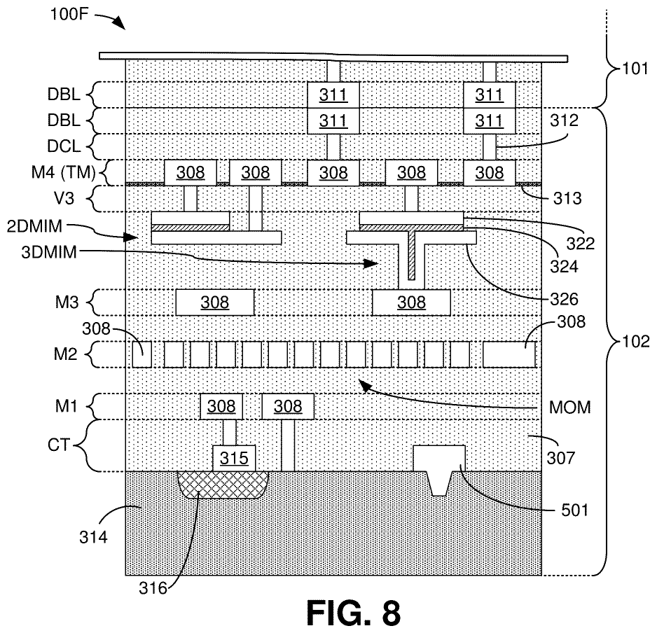

FIG. 8 illustrates a cross-sectional view of some embodiments of an IC imaging device 100F including a pixel circuit employing a multi-capacitor LOFIC arrangement, according to the present disclosure. Unlike the previous embodiments described above, IC device 100F employs four capacitors in a LOFIC arrangement. More specifically, as depicted in FIG. 8, the roles of capacitors C1, C2, C3, and C4 of FIGS. 1A and 1B may be filled by capacitor structures 501, MOM, 2DMIM, and 3DMIM, respectively.

In detail, in a high conversion gain HCG mode, none of capacitor structures 501, MOM, 2DMIM, or 3DMIM may be coupled to region FD. In a first moderate conversion gain MCG1 mode, in some embodiments, capacitor structure 501 may be coupled in parallel to floating diffusion region FD. In a second moderate conversion gain MCG2 mode, capacitor structures 501 and MOM may be coupled in parallel to floating diffusion region FD. Further, in a third moderate conversion gain MCG3 mode, capacitor structures 501, MOM, and 2DMIM may be coupled in parallel to floating diffusion region FE, while in a low conversion gain LCG mode, capacitor structures 501, MOM, 2DMIM, and 3DMIM may be coupled in parallel to region FD. Consequently, the overall signal-to-noise ratio exhibited by embodiments of IC device 100F of FIG. 8 that employ HCG mode, MCG1 mode, MCG2 mode, MCG3 mode, and LCG mode may resemble that depicted above in FIG. 2D.

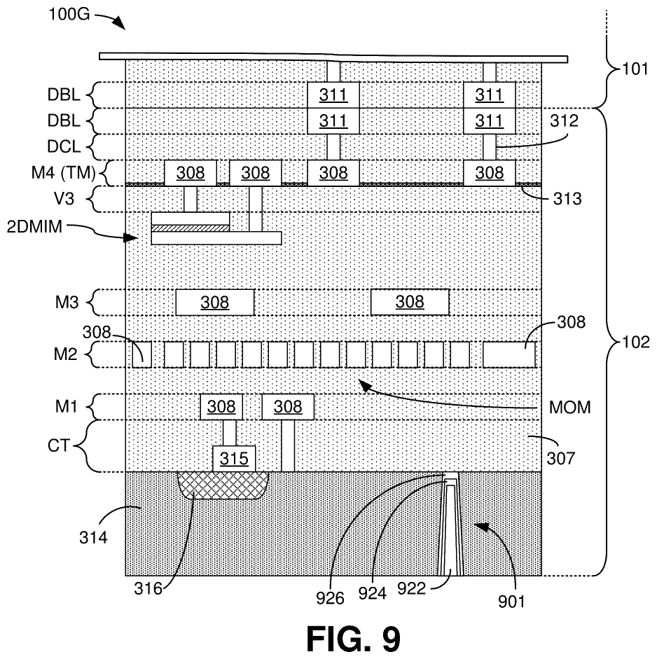

FIGS. 9, 10, 11, and 12 illustrate cross-sectional views of some embodiments of IC imaging devices 100G, 100H, 100I, and 100J, respectively, including a pixel circuit employing a multi-capacitor LOFIC arrangement, according to the present disclosure. Each of IC devices 100G through 100J includes the same capacitor structures as each of IC devices 100C through 100F, respectively, of FIGS. 5 through 8, with the exception of capacitor structure 501 in FIGS. 5 through 8, which is replaced as capacitor C1 of FIGS. 1A and 1B in IC devices 100G through 100J with a second substrate capacitor structure 901, as shown in FIGS. 9 through 12.

In some embodiments, as depicted in FIG. 9, second substrate capacitor structure 901 may have a deep trench isolation (DTI)-like shape extending upward at a lower side of substrate 314 into a trench thereof. Further, in some embodiments, capacitor structure 901 may have a MIM-like capacitor structure, with a first conductive element 926 lining the trench, a dielectric element 924 disposed on first conductive element 926, and a second conductive element 922 disposed on dielectric element 924 and serving as a plug element. Further, in some embodiments, the materials included in first conductive element 926, dielectric element 924, and second conductive element 922 may include those described above for first conductive element 326, dielectric element 324, and second conductive element 322 of capacitor structures 2DMIM and 3DMIM of FIG. 3, as described above.

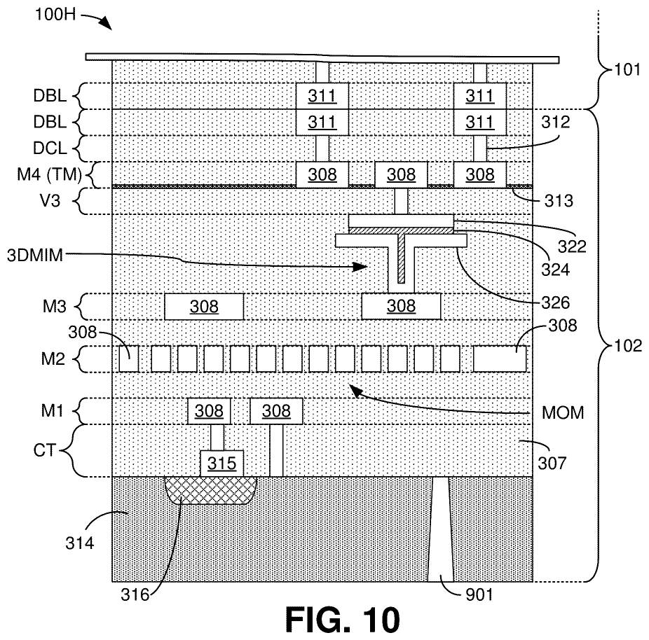

In other embodiments, as shown in FIGS. 10 through 16, second substrate capacitor structure 901 may be a single conductive structure that is primarily vertically oriented and disposed within a trench formed in the lower side of substrate 314 of second IC die 102. In some embodiments, capacitor structure 901 may include polycrystalline silicon (poly-Si), a metal, a metal alloy, or another conductive material. Consequently, such material may be different from that used for other deep trench isolation structures that may be formed using an insulating or dielectric material. As is the case with similar embodiments of capacitor structure 501 described above, capacitor structure 901 may possess an associated (e.g., inherent) capacitance that may be employed as a capacitor structure (e.g., capacitor C1 of FIGS. 1A and 1B) in a LOFIC arrangement. In some embodiments, capacitor structure 901 may include polycrystalline silicon (poly-Si), a metal, a metal alloy, or another conductive material. In other embodiments, either the MIM-like structure of FIG. 9 or the single conductive structure of FIGS. 10 through 16 may be used in any embodiment that employs second substrate capacitor structure 901.

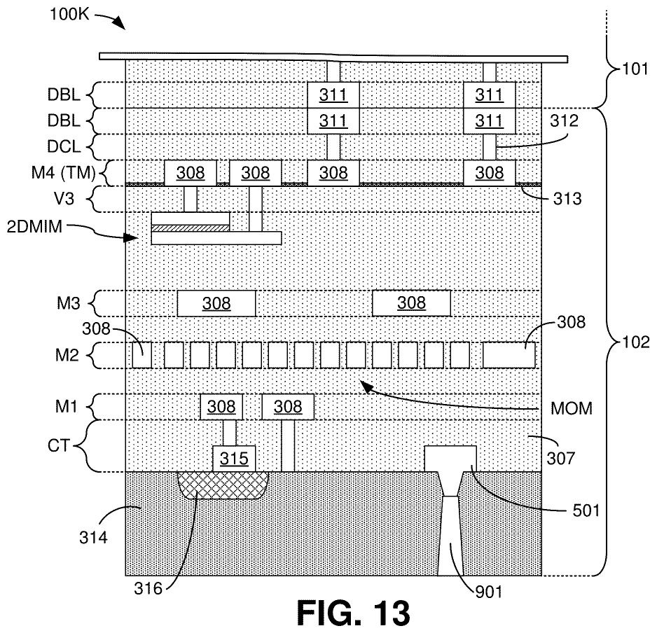

FIGS. 13, 14, 15, and 16 illustrate cross-sectional views of some embodiments of IC imaging devices 100K, 100L, 100M, and 100N, respectively, including a pixel circuit employing a multi-capacitor LOFIC arrangement, according to the present disclosure. Each of IC devices 100K through 100N includes the same capacitor structures as each of IC devices 100C through 100F, respectively, of FIGS. 5 through 8, with the exception of capacitor structure 501 of FIGS. 5 through 8, which is replaced as capacitor C1 of FIGS. 1A and 1B in IC devices 100K through 100N with capacitor structure 501 in combination with capacitor structure 901, as shown in FIGS. 13 through 16.

In some embodiments, as depicted in FIGS. 13 through 16, as discussed earlier, capacitor structure 501 may be primarily vertically oriented, and that at least partially extends from an upper side of substrate 314 (e.g., within dielectric structure 307) downward into substrate 314. Oppositely, as described above, capacitor structure 901 may be disposed within a trench formed within substrate 314 by way of a bottom side of substrate 314. Accordingly, in some embodiments (e.g., when capacitor structures 501 and 901 are single conductive structures), capacitor structure 901 may contact a bottom surface of capacitor structure 501 to form a contiguous, vertically oriented conductive structure that extends through substrate 314. In some embodiments, capacitor structures 501 and 901 may include polycrystalline silicon (poly-Si), a metal, a metal alloy, or another conductive material. As is the case with individual capacitor structures 501 and 901 described above, capacitor structure 901 in combination (e.g., in direct contact) with capacitor structure 501 may possess a single associated (e.g., inherent) capacitance that may be employed as a capacitor structure (e.g., capacitor C1 of FIGS. 1A and 1B) in a LOFIC arrangement.

In other embodiments (e.g., when capacitor structures 501 and 901 are MIM-like capacitor structures), capacitor structure 901 may contact a bottom surface of capacitor structure 501, thus placing capacitor structures 501 and 901 in series, thus potentially producing a capacitance that is less than the capacitance of either capacitor structure 501 or capacitor structure 901.

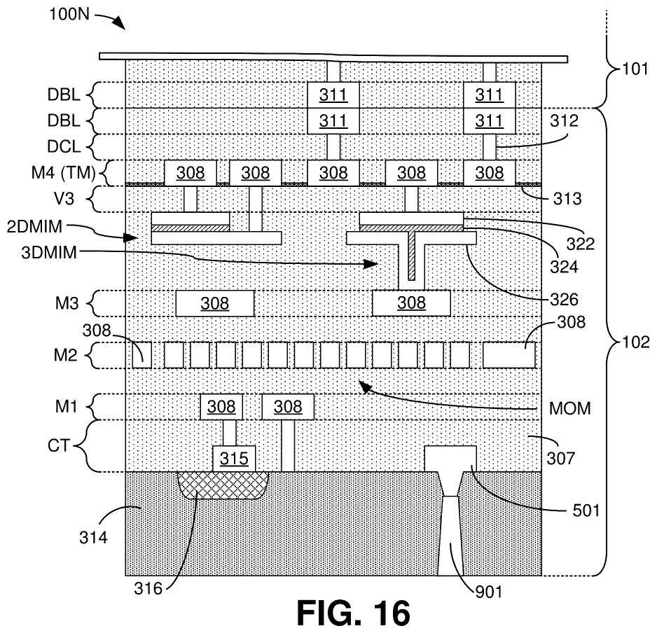

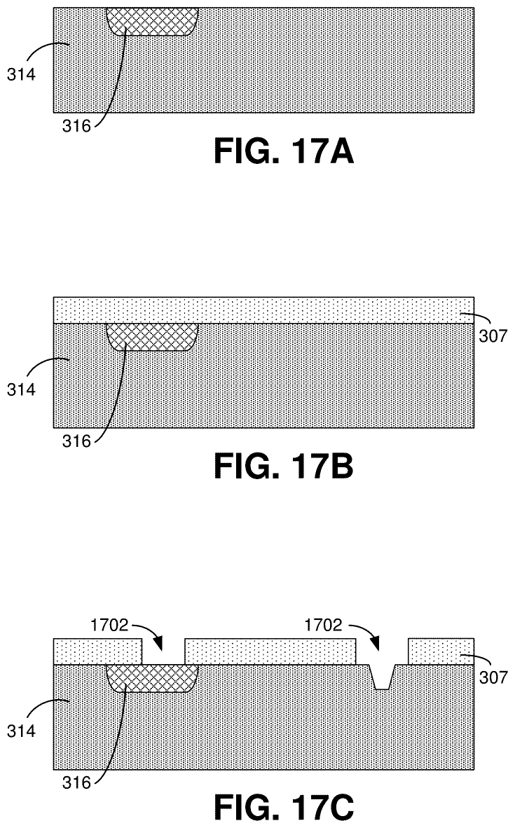

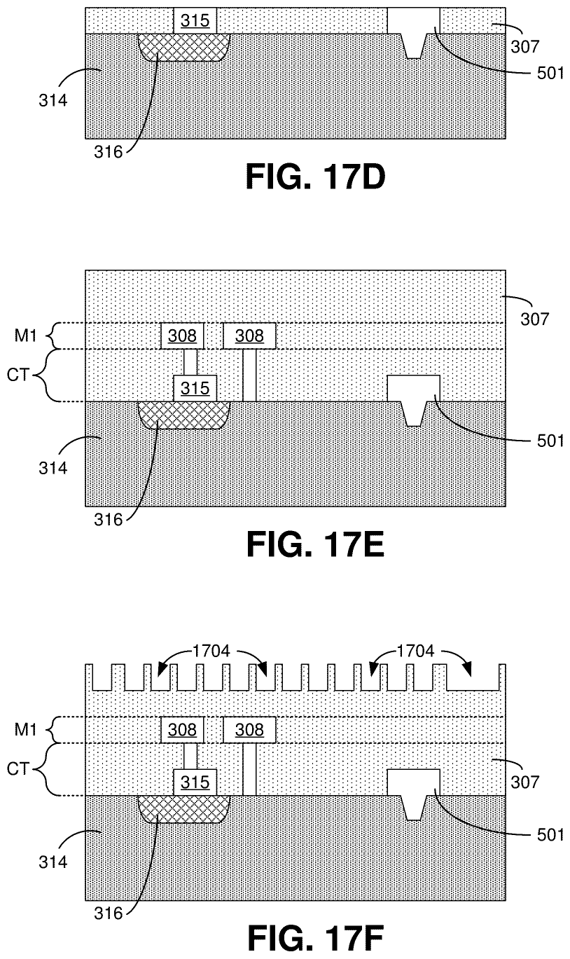

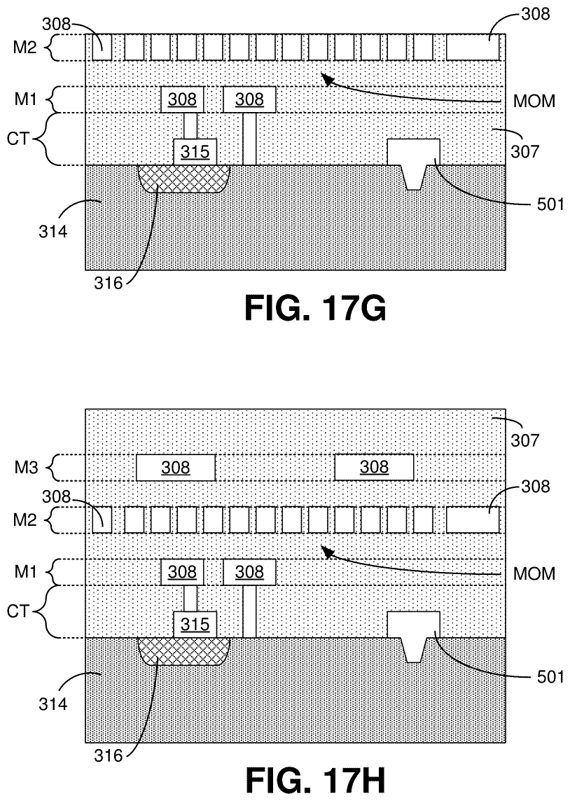

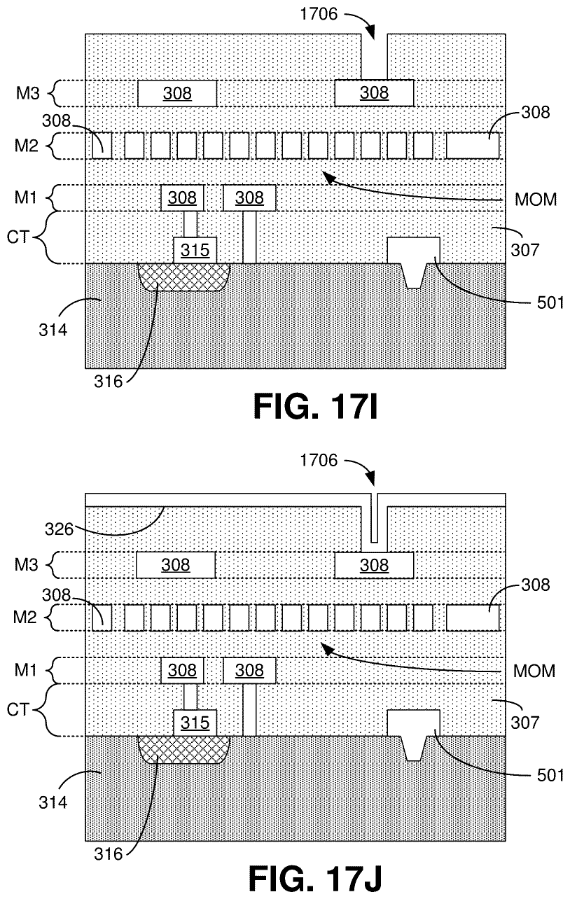

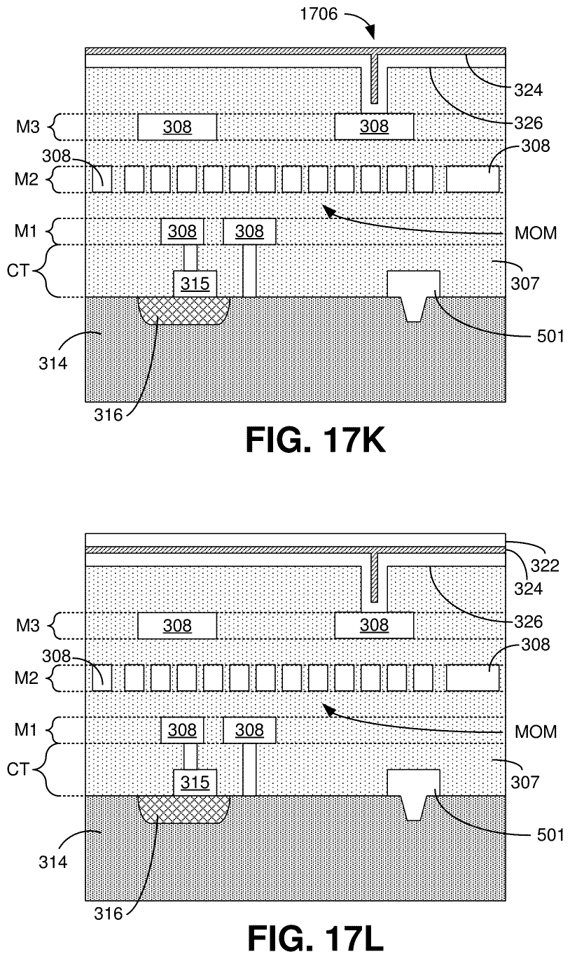

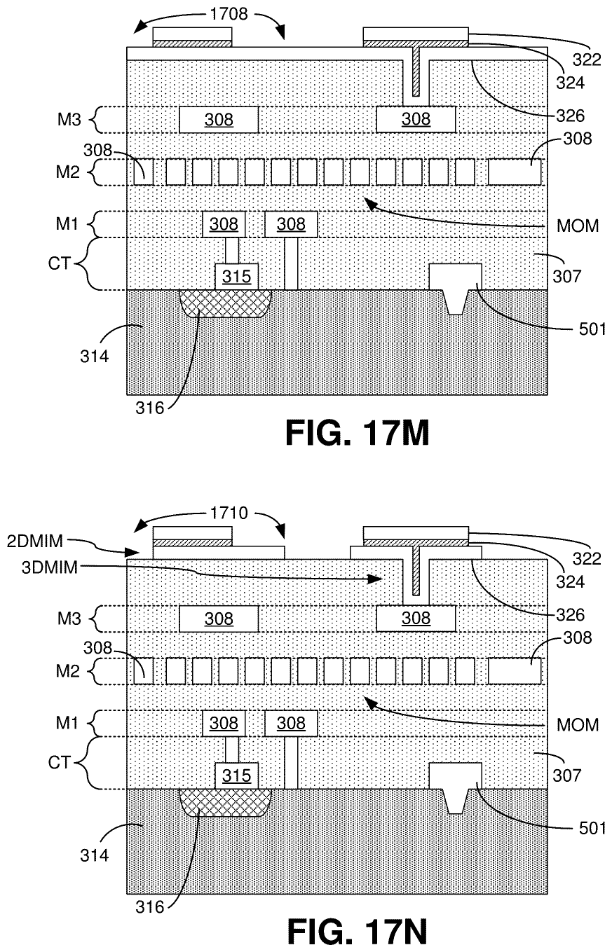

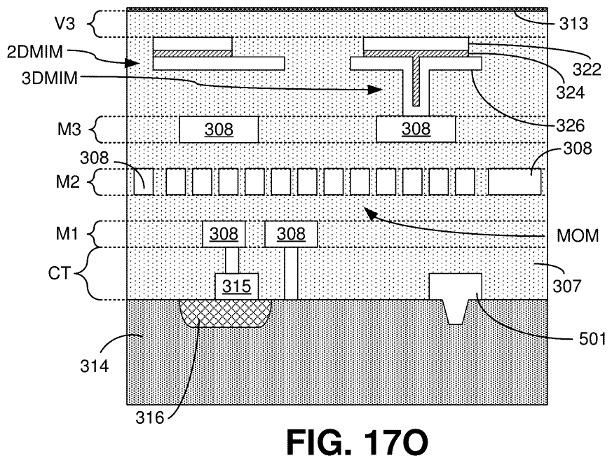

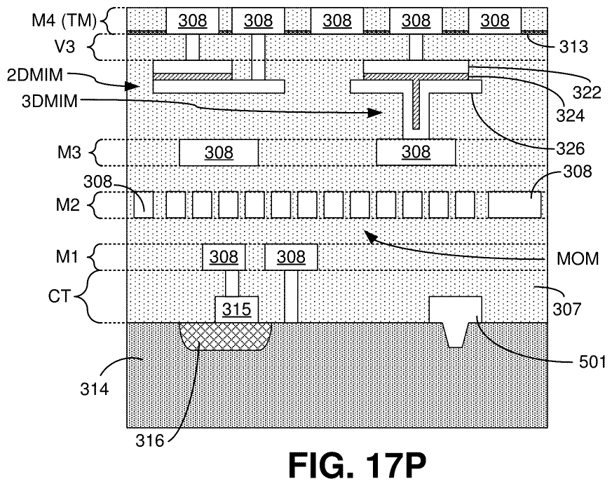

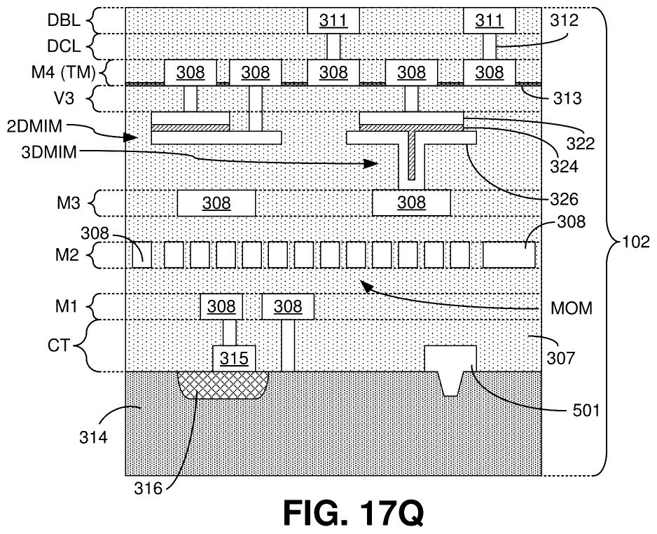

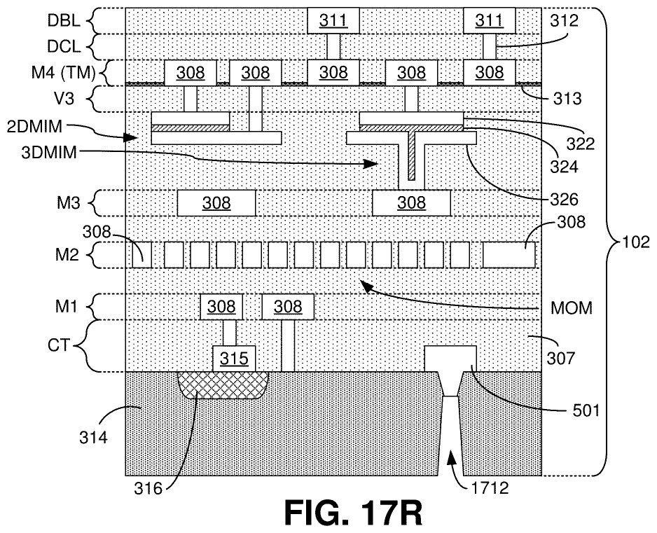

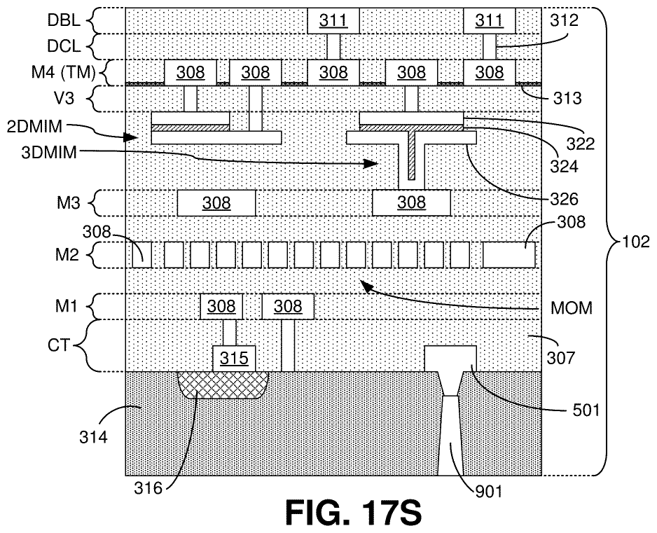

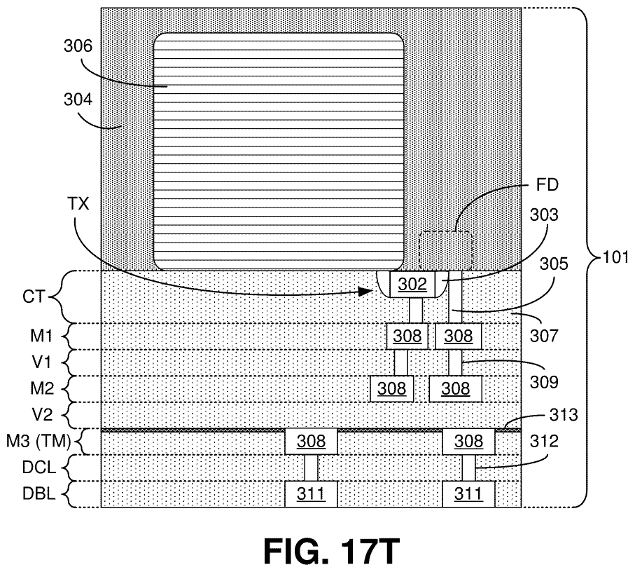

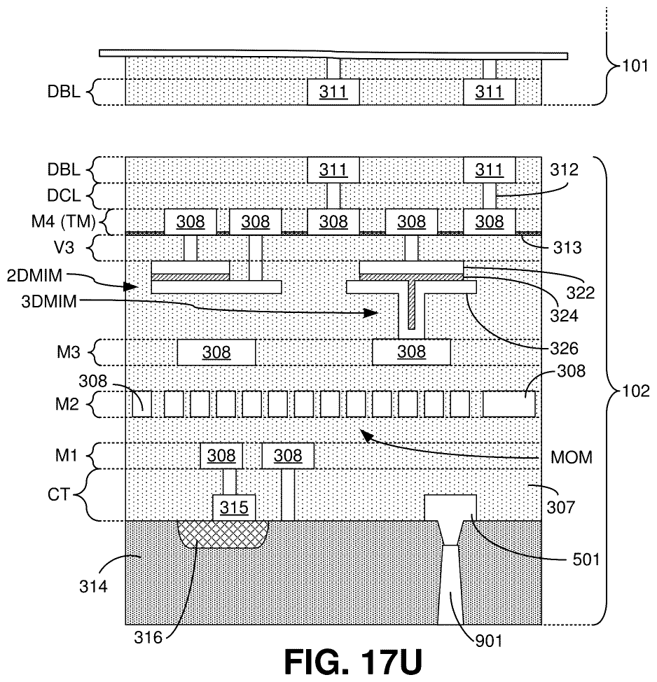

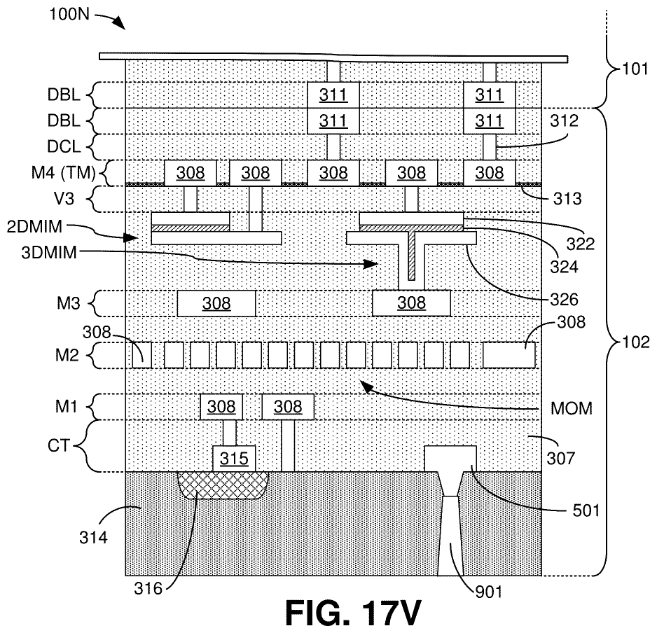

FIGS. 17A through 17W illustrate cross-sectional views of some embodiments of an IC imaging device 100N of FIG. 16, including a pixel circuit employing a multi-capacitor LOFIC arrangement at various stages of manufacture, according to the present disclosure. Although FIGS. 17A through 17W are described as a series of acts, it will be appreciated that these acts are not limiting in that the order of the acts within each series can be altered in other embodiments, and the methods disclosed are also applicable to other structures. In other embodiments, some acts that are illustrated and/or described may be omitted in whole or in part.

For example, FIG. 17A illustrates a substrate 314 for second IC die 102. In some embodiments, substrate 314 may include at least one doped region 316 for circuitry to be employed in second IC die 102 (e.g., timing and processing circuitry 110, conversion gain transistors CG1, CG2, and so on of FIGS. 1A and 1B).

FIG. 17B illustrates the forming (e.g., deposition) of at least one layer of dielectric material for dielectric structure 307 on substrate 314. In some embodiments, the dielectric material may include, but is not limited to, silicon oxide (SiOx) (e.g., silicon oxide (SiO2)), silicon nitride (SiN), silicon carbide (SiC), carbon-doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like.

FIG. 17C illustrates the removal (e.g., by way of photolithography and etching) of portions of dielectric material to form one or more trenches 1702 in dielectric structure 307 for subsequent forming of conductive structures thereon. In some embodiments, such removal may extend at least partially into substrate 314, such as for a capacitor structure.

FIG. 17D illustrates the forming (e.g., deposition) of conductive material in trenches 1702, such as for a capacitor structure 501. In some embodiments, other conductive structures (e.g., a conductive structure 315 that couples doped region 316 to another portion of a conductive structure) may be formed concurrently with capacitor structure 501. In some embodiments, such conductive material may include polycrystalline silicon (poly-Si) or another conductive material. In other embodiments, capacitor structure 501 may have a MIM-like structure, as shown in FIG. 5, in which first conductive element 526 is deposited in trench 1702, followed by deposition of dielectric element 524 on first conductive element 526, followed by deposition of second conductive element 522 on dielectric element 524.

FIG. 17E illustrates the forming (e.g., deposition, along with lithography and etching) of additional dielectric and conductive material to add conductive structures 308 and associated conductive contacts within dielectric structure 307 (e.g., included in metal layer M1 and contact layer CT).

FIG. 17F illustrates the removal (e.g., via lithography and etching) of trenches 1704 in an upper side of dielectric structure 307 to subsequently form another capacitor structure and potentially other conductive structures.

FIG. 17G illustrates the forming (e.g., deposition) of conductive material to form capacitor structure MOM. In some embodiments, additional conductive material may be applied concurrently to form other conductive structures 308. Also, in some embodiments, such conductive material may include, but is not limited to, copper (Cu), another metal or metal alloy, or another conductive material (e.g., included in metal layer M2). Further, in some embodiments, such forming may include a subsequent chemical and mechanical planarization (CMP) operation or another planarization technique.

FIG. 17H illustrates the forming (e.g., deposition, along with lithography and etching) of additional dielectric and conductive material to add conductive structures 308 and associated conductive vias within dielectric structure 307 (e.g., some of which may be included in a metal layer M3).

FIG. 17I illustrates the removal (e.g., via lithography and etching) of dielectric material from an upper side of dielectric structure 307 for forming additional capacitor structures. In some embodiments, one or more of trenches 1706 may extend downward to a conductive structure 308 to be coupled with one or more of the capacitor structures.

FIG. 17J illustrates the conformal forming (e.g., conformal deposition) of conductive material to form a conductive layer for first conductive elements 326 for one or more capacitor structures (e.g., capacitor structures 2DMIM and 3DMIM of FIG. 16) that conformally extends into trench 1706. In some embodiments, the conductive material may include, but is not limited to, titanium nitride (TiN), an aluminum-copper (AlCu) alloy, tungsten (W), and/or another metal or metal alloy, polycrystalline silicon (poly-Si), and/or another conductive material.

FIG. 17K illustrates the forming (e.g., deposition) of a dielectric material for use as dielectric elements 324 for capacitor structures 2DMIM and 3DMIM. The dielectric material is formed on the prior conductive layer, including filling a remainder of trench 1706. In some embodiments, the dielectric material may include, but is not limited to, a high-κ dielectric material, such as hafnium silicate (HfO₆Si₂), zirconium silicate (ZrSiO₄), hafnium dioxide (HfO₂), zirconium dioxide (ZrO₂), and/or the like. In other embodiments, other dielectric materials that are not high-κ dielectric or insulating materials may be employed.

FIG. 17L illustrates the forming (e.g., deposition) of additional conductive material on the previously added dielectric material, where the additional conductive material is to be employed to form second conductive elements 322. In some embodiments, the additional conductive material may be the same as that employed for first conductive elements 326.

FIG. 17M illustrates the removal (e.g., by lithography and etching) of one or more portions 1708 of the previously added conductive layer and underlying dielectric layer to form dielectric elements 324 and second conductive elements 322 for capacitor structures 2DMIM and 3DMIM.

FIG. 17N illustrates the removal (e.g., by lithography and etching) of one or more portions 1710 of the lower conductive layer underlying the dielectric layer to form first conductive elements 326 for capacitor structures 2DMIM and 3DMIM.

FIG. 17O illustrates the forming (e.g., deposition) of additional material for dielectric structure 307 (e.g., as part of a via layer V3). Additionally, in some embodiments, an etch stop layer 313 may be formed on the added dielectric material. In some embodiments, etch stop layer 313 may include one or more of silicon nitride (SiN), silicon carbide (SiC), silicon carbonitride (SiCN), or another dielectric material.

FIG. 17P illustrates the forming (e.g., by way of photolithography, etching, and subsequent filling) of one or more conductive structures 308 (e.g., in a top metal layer (TM)) and conductive vias (e.g., within a via layer V3) within additional dielectric material of dielectric structure 307, and possibly through etch stop layer 313. In some embodiments, one or more such conductive structures 308 may be coupled to first conductive element 326 and/or second conductive element 322 of capacitor structures 2DMIM and/or 3DMIM (e.g., for connection with conversion gain transistors, as discussed above).

FIG. 17Q illustrates the forming (e.g., by way of photolithography, etching, and subsequent filling) of one or more conductive structures 311 (e.g., in a bond layer DBL) and conductive contacts 312 (e.g., in a bond contact layer DCL) within additional dielectric material of dielectric structure 307. In addition, a CMP operation or other planarization technique may be performed thereafter to planarize an upper side of second IC die 102. As discussed above, in some embodiments, such structures may facilitate electrical connections with first IC die 101 of FIG. 16, as well as bonding of second IC die 102 with first IC die 101.

FIG. 17R illustrates the removal (e.g., via lithography and etching) of a portion of material from a lower side of substrate 314 upward to a lower side of capacitor structure 501 to form a trench 1712. Thereafter, FIG. 17S illustrates the forming (e.g., deposition) of conductive material in trench 1712 to form capacitor structure 901 in contact with capacitor structure 501. In some embodiments, capacitor structure 901 may include polycrystalline silicon (poly-Si), a metal, a metal alloy, or another conductive material. In some embodiments, capacitor structure 901 may instead include a MIM-like structure, as shown in FIG. 9, in which first conductive element 926 is deposited in trench 1712, followed by deposition of dielectric element 924 on first conductive element 926, followed by deposition of second conductive element 922 on dielectric element 924. In some embodiments, second IC die 102 may be inverted or flipped to facilitate access for the operations described above with respect to FIGS. 17R and 17S.

FIG. 17T illustrates the providing of first IC die 101 after fabrication, in which first IC die 101 includes a substrate 304 with photosensitive region 306, floating diffusion FD, and transfer transistor TX, as described above.

FIG. 17U illustrates the positioning of first IC die 101 over second IC die 102, and FIG. 17V illustrates the bonding (e.g., via heat-based bonding) of an upper side of first IC die 101 with an upper side of second IC die 102. In some embodiments, this bonding may be performed by placing the upper side of first IC die 101 and the upper side second IC die 102 (e.g., at room temperature) together to bond dielectric structures 307, and then heating the resulting assembly to cause each of conductive structures 311 of first IC die 101 to contact a corresponding one of conductive structures 311 of second IC die 102.

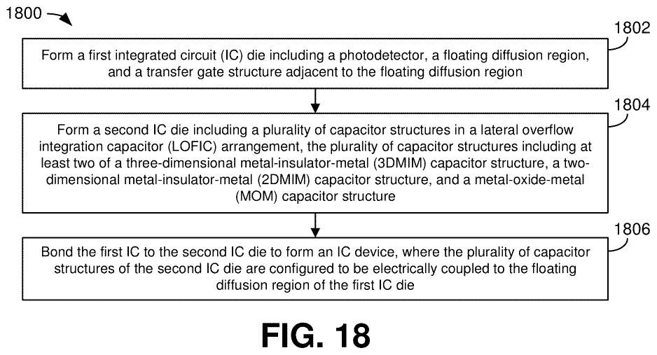

FIG. 18 illustrates a methodology 1800 of forming an IC imaging device (e.g., IC imaging devices 100A through 100N of FIGS. 3 through 16) employing a multi-capacitor LOFIC arrangement, in accordance with some embodiments of the present disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At Act 1802, a first IC die (e.g., first IC die 101 of FIGS. 3 and 17V) is formed that includes a photodetector (e.g., photosensitive region 306 and associated portion of substrate 304 of FIG. 3), a floating diffusion region (e.g., region FD of FIG. 3), and a transfer gate structure (e.g., gate structure 302 of FIG. 3) adjacent to the floating diffusion region. FIG. 17T illustrates a cross-sectional view of some embodiments corresponding to Act 1802.

At Act 1804, a second IC die (e.g., second IC die of FIGS. 3 and 17V) is formed that includes a plurality of capacitor structures (e.g., capacitor structures MOM, 2DMIM, and/or 3DMIM of FIG. 17U) in a lateral overflow integration capacitor (LOFIC) arrangement, the plurality of capacitor structures including at least two of a three-dimensional metal-insulator-metal (3DMIM) capacitor structure (e.g., capacitor structure 3DMIM of FIG. 17U), a two-dimensional metal-insulator-metal (2DMIM) capacitor structure (e.g., capacitor structure 2DMIM of FIG. 17U) and a metal-oxide-metal (MOM) capacitor structure (e.g., capacitor structure MOM of FIG. 17U). FIGS. 17A through 17S illustrate cross-sectional views of some embodiments corresponding to Act 1804.

At Act 1806, the first IC die is bonded to the second IC die to form an IC device (e.g., IC devices 100A through 100N of FIGS. 3 through 16). The plurality of capacitor structures of the second IC die are electrically coupled to the floating diffusion region of the first IC die. FIGS. 17U and 17V illustrate cross-sectional views of some embodiments corresponding to Act 1806.

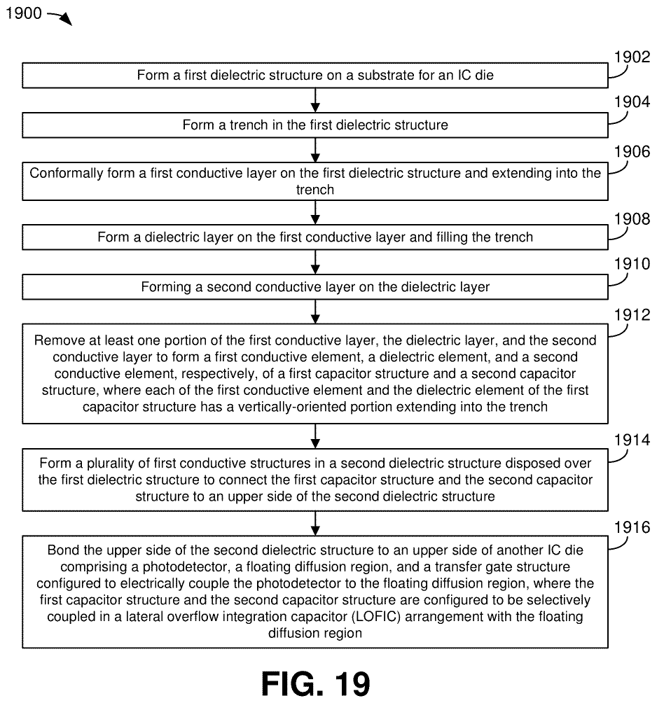

FIG. 19 illustrates another methodology 1900 of forming an IC imaging device (e.g., IC imaging device 100N of FIG. 16) employing a multi-capacitor LOFIC arrangement, in accordance with some embodiments of the present disclosure.

At Act 1902, first dielectric structure (e.g., dielectric structure 307 of FIG. 17B) is formed on a substrate (e.g., substrate 314 of FIG. 17B) for an IC die (e.g., second IC die 102 of FIG. 16). FIGS. 17B through 17H illustrate cross-sectional views of some embodiments corresponding to Act 1902.

At Act 1904, a trench (e.g., trench 1706 of FIG. 7I) is formed on the first dielectric structure. FIG. 7I illustrates a cross-sectional view of some embodiments corresponding to Act 1904.

At Act 1906, a first conductive layer (e.g., conductive material for first conductive elements 326 of FIG. 17J) is conformally formed on the first dielectric structure and extending into the trench. FIG. 17J illustrates a cross-sectional view of some embodiments corresponding to Act 1906.

At Act 1908, a dielectric layer (e.g., material for dielectric element 324 of FIG. 17K) is formed on the first conductive layer. FIG. 17K illustrates a cross-sectional view of some embodiments corresponding to Act 1908.

At Act 1910, a second conductive layer (e.g., material for second conductive elements 322 of FIG. 17L) is formed on the dielectric layer. FIG. 17L illustrates a cross-sectional view of some embodiments corresponding to Act 1910.

At Act 1912, at least one portion of the first conductive layer, the dielectric layer, and the second conductive layer are removed to form a first conductive element, a dielectric element, and a second conductive element, respectively, of a first capacitor structure (e.g., capacitor structure 3DMIM of FIG. 17N) and a second capacitor structure (e.g., capacitor structure 2DMIM of FIG. 17N). FIGS. 17M and 17N illustrate cross-sectional views of some embodiments corresponding to Act 1912.

At Act 1914, a plurality of conductive structures (e.g., conductive structures 308 and 311, conductive contacts 312, and so on of FIG. 17Q) are formed in a second dielectric structure (e.g., additional material for dielectric structure 307) disposed over the first dielectric structure to connect the first capacitor structure and the second capacitor structure to an upper side of the second dielectric structure. FIGS. 17O through 17Q illustrate cross-sectional views of some embodiments corresponding to Act 1914.

At Act 1916, the upper side of the second dielectric structure is bonded to an upper side of another IC die (e.g., first IC die 101 of FIG. 17T) including a photodetector (e.g., photodetector PD of FIG. 3), a floating diffusion region (e.g., region FD of FIG. 3), and a transfer gate structure (e.g., gate structure 302 of FIG. 3) configured to electrically couple the photodetector to the floating diffusion region, where the first capacitor structure and the second capacitor structure are configured to be selectively coupled in a lateral overflow integration capacitor (LOFIC) arrangement with the floating diffusion region. FIGS. 17U and 17V illustrate cross-sectional views of some embodiments corresponding to Act 1916.

Some embodiments relate to an IC device. The IC device includes a photodetector, a floating diffusion region, a transfer gate structure configured to electrically couple the photodetector to the floating diffusion region, a plurality of capacitor structures including a first capacitor structure and a second capacitor structure, and a plurality of transistor structures including a first transistor structure and a second transistor structure. The second transistor structure is configured to electrically couple the second capacitor structure to the floating diffusion region. The first transistor structure is configured to electrically couple the first capacitor structure to the second capacitor structure in parallel. One of the first capacitor structure or the second capacitor structure includes at least a portion of a first conductive element and a portion of a second conductive element laterally separated from each other. The other one of the first capacitor structure or the second capacitor structure includes at least a portion of a first conductive element and a portion of a second conductive element vertically separated from each other.

Some embodiments relate to a method. The method includes forming a first integrated circuit (IC) die including a photodetector, a floating diffusion region, and a transfer gate structure adjacent to the floating diffusion region; forming a second IC die including a plurality of capacitor structures in a lateral overflow integration capacitor (LOFIC) arrangement; and bonding the first IC to the second IC die to form an IC device, wherein the plurality of capacitor structures of the second IC die are configured to be electrically coupled to the floating diffusion region of the first IC die. The plurality of capacitor structures includes at least two of: a first structure including: a first conductive element having a laterally-oriented portion and a vertically-oriented portion; a dielectric element disposed on the first conductive element and having a laterally-oriented portion and a vertically-oriented portion; and a second conductive element that is planar, laterally-oriented, and disposed on the dielectric element; a second capacitor structure including: a first conductive element and a second conductive element that are planar and laterally-oriented; and a dielectric element disposed on the first conductive element, wherein the second conductive element is disposed on the dielectric element; or a third capacitor structure including a first conductive element and a second conductive element that are planar, laterally-oriented, and spaced laterally therebetween.

Some embodiments relate to another method. The method includes forming a first dielectric structure on a substrate for an IC die; forming a trench in the first dielectric structure; conformally forming a first conductive layer on the first dielectric structure and extending into the trench; forming a dielectric layer on the first conductive layer and filling the trench; forming a second conductive layer on the dielectric layer; removing at least one portion of the first conductive layer, the dielectric layer, and the second conductive layer to form a first conductive element, a dielectric element, and a second conductive element, respectively, of a first capacitor structure and a second capacitor structure, wherein each of the first conductive element and the dielectric element of the first capacitor structure has a vertically-oriented portion extending into the trench; forming a plurality of first conductive structures in a second dielectric structure disposed over the first dielectric structure to connect the first capacitor structure and the second capacitor structure to an upper side of the second dielectric structure; and bonding the upper side of the second dielectric structure to an upper side of another IC die including a photodetector, a floating diffusion region, and a transfer gate structure configured to electrically couple the photodetector to the floating diffusion region, wherein the first capacitor structure and the second capacitor structure are configured to be selectively coupled in a lateral overflow integration capacitor (LOFIC) arrangement with the floating diffusion region.

It will be appreciated that in this written description, as well as in the claims below, the terms “first”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a photodetector;
a floating diffusion region;
a transfer gate structure configured to electrically couple the photodetector to the floating diffusion region;
a plurality of capacitor structures comprising a first capacitor structure and a second capacitor structure; and
a plurality of transistor structures comprising a first transistor structure and a second transistor structure; wherein
the second transistor structure is configured to electrically couple the second capacitor structure to the floating diffusion region;
the first transistor structure is configured to electrically couple the first capacitor structure to the second capacitor structure in parallel;
one of the first capacitor structure or the second capacitor structure comprises at least a portion of a first conductive element and a portion of a second conductive element laterally separated from each other; and
the other one of the first capacitor structure or the second capacitor structure comprises at least a portion of a first conductive element and a portion of a second conductive element vertically separated from each other.

2. The IC device of claim 1, wherein:
the first conductive element of the first capacitor structure has a laterally-oriented portion and a vertically-oriented portion;
the first capacitor structure comprises a dielectric element disposed on the first conductive element of the first capacitor structure and has a laterally-oriented portion and a vertically-oriented portion;
the second conductive element of the first capacitor structure is planar, laterally-oriented, and disposed on the dielectric element of the first capacitor structure;
the first and second conductive elements of the second capacitor structure are planar and laterally-oriented;
the second capacitor structure comprises a dielectric element disposed on the first conductive element of the second capacitor structure; and
the second conductive element of the second capacitor structure is disposed on the dielectric element of the second capacitor structure.

3. The IC device of claim 2, wherein:
the second conductive element of the first capacitor structure and the second conductive element of the second capacitor structure are disposed a same distance from a substrate of the IC device.

4. The IC device of claim 2, wherein:
the plurality of capacitor structures comprises a third capacitor structure;
the plurality of transistor structures comprises a third transistor structure configured to electrically couple the third capacitor structure to the floating diffusion region; and
the second transistor structure is further configured to electrically couple the second capacitor structure to the third capacitor structure in parallel.

5. The IC device of claim 4, wherein the third capacitor structure comprises a first conductive element and a second conductive element that are planar, laterally-oriented, and spaced laterally therebetween.

6. The IC device of claim 5, wherein:
the third capacitor structure is disposed between at least at least one of the first capacitor structure or the second capacitor structure and a substrate of the IC device.

7. The IC device of claim 4, wherein:
the plurality of capacitor structures comprises a fourth capacitor structure;
the plurality of transistor structures comprises a fourth transistor structure configured to electrically couple the fourth capacitor structure to the floating diffusion region; and
the third transistor structure is further configured to electrically couple the third capacitor structure to the fourth capacitor structure in parallel.

8. The IC device of claim 7, wherein the fourth capacitor structure comprises at least one vertically-oriented capacitor structure that is at least partially disposed within a substrate of the IC device.

9. The IC device of claim 8, wherein:
the at least one vertically-oriented capacitor structure comprises at least one of:
a first vertically-oriented capacitor structure extending partially into an upper side of a substrate of the IC device; or
a second vertically-oriented capacitor structure extending partially into a lower side of the substrate; and
when the at least one vertically-oriented capacitor structure comprises the first vertically-oriented capacitor structure and the second vertically-oriented capacitor structure, the first vertically-oriented capacitor structure contacts the second vertically-oriented capacitor structure within the substrate.

10. The IC device of claim 1, wherein:
the first conductive element of the first capacitor structure has a laterally-oriented portion and a vertically-oriented portion;
the first capacitor structure comprises a dielectric element disposed on the first conductive element of the first capacitor structure and has a laterally-oriented portion and a vertically-oriented portion;
the second conductive element of the first capacitor structure is planar, laterally-oriented, and disposed on the dielectric element of the first capacitor structure; and
the second capacitor structure comprises a first conductive element and a second conductive element that are planar, laterally-oriented, and spaced laterally therebetween.

11. The IC device of claim 10, wherein:
the plurality of capacitor structures comprises a third capacitor structure;
the plurality of transistor structures comprises a third transistor structure configured to electrically couple the third capacitor structure to the floating diffusion region;
the second transistor structure is further configured to electrically couple the second capacitor structure to the third capacitor structure in parallel; and
the third capacitor structure comprises at least one vertically-oriented capacitor structure that is at least partially disposed within a substrate of the IC device.

12. The IC device of claim 1, wherein:
the first and second conductive elements of the first capacitor structure are planar and laterally-oriented;
the first capacitor structure comprises a dielectric element disposed on the first conductive element of the first capacitor structure;
the second conductive element of the first capacitor structure is disposed on the dielectric element of the first capacitor structure; and
the second capacitor structure comprises a first conductive element and a second conductive element that are planar, laterally-oriented, and spaced laterally therebetween.

13. The IC device of claim 12, wherein:
the plurality of capacitor structures comprises a third capacitor structure;
the plurality of transistor structures comprises a third transistor structure configured to electrically couple the third capacitor structure to the floating diffusion region;
the second transistor structure is further configured to electrically couple the second capacitor structure to the third capacitor structure in parallel; and
the third capacitor structure comprises at least one vertically-oriented capacitor structure that is at least partially disposed within a substrate of the IC device.

14. A method, comprising:
forming a first integrated circuit (IC) die comprising a photodetector, a floating diffusion region, and a transfer gate structure adjacent to the floating diffusion region;
forming a second IC die comprising a plurality of capacitor structures in a lateral overflow integration capacitor (LOFIC) arrangement, the plurality of capacitor structures comprising at least two of:
a first capacitor structure comprising:
a first conductive element having a laterally-oriented portion and a vertically-oriented portion;
a dielectric element disposed on the first conductive element and having a laterally-oriented portion and a vertically-oriented portion; and
a second conductive element that is planar, laterally-oriented, and disposed on the dielectric element;
a second capacitor structure comprising:
a first conductive element and a second conductive element that are planar and laterally-oriented; and
a dielectric element disposed on the first conductive element, wherein the second conductive element is disposed on the dielectric element; or
a third capacitor structure comprising a first conductive element and a second conductive element that are planar, laterally-oriented, and spaced laterally therebetween: and
bonding the first IC to the second IC die to form an IC device, wherein the plurality of capacitor structures of the second IC die are configured to be electrically coupled to the floating diffusion region of the first IC die.

15. The method of claim 14, wherein:
the plurality of capacitor structures comprises the first capacitor structure and the second capacitor structure; and
the second conductive element of the first capacitor structure and the second conductive element of the second capacitor structure are disposed laterally to each other and at a same vertical distance from a substrate of the second IC die.

16. The method of claim 14, wherein:
the plurality of capacitor structures comprises the third capacitor structure and at least one of the first capacitor structure or the second capacitor structure; and
the third capacitor structure is disposed between the at least one of the first capacitor structure or the second capacitor structure and a substrate of the second IC die.

17. The method of claim 14, wherein the plurality of capacitor structures further comprises at least one vertically-oriented capacitor structure at least partially disposed within a substrate of the second IC die.

18. A method, comprising:
forming a first dielectric structure on a substrate for an IC die;
forming a trench in the first dielectric structure;
conformally forming a first conductive layer on the first dielectric structure and extending into the trench;
forming a dielectric layer on the first conductive layer and filling the trench;
forming a second conductive layer on the dielectric layer;
removing at least one portion of the first conductive layer, the dielectric layer, and the second conductive layer to form a first conductive element, a dielectric element, and a second conductive element, respectively, of a first capacitor structure and a second capacitor structure, wherein each of the first conductive element and the dielectric element of the first capacitor structure has a vertically-oriented portion extending into the trench;
forming a plurality of first conductive structures in a second dielectric structure disposed over the first dielectric structure to connect the first capacitor structure and the second capacitor structure to an upper side of the second dielectric structure; and
bonding the upper side of the second dielectric structure to an upper side of another IC die comprising a photodetector, a floating diffusion region, and a transfer gate structure configured to electrically couple the photodetector to the floating diffusion region, wherein the first capacitor structure and the second capacitor structure are configured to be selectively coupled in a lateral overflow integration capacitor (LOFIC) arrangement with the floating diffusion region.

19. The method of claim 18, wherein:
the first capacitor structure is a farthest capacitor structure in the LOFIC arrangement relative to the floating diffusion region; and
the second capacitor structure is a next-to-farthest capacitor structure in the LOFIC arrangement relative to the floating diffusion region.

20. The method of claim 18, further comprising forming a third capacitor structure within the first dielectric structure prior to forming the first conductive layer, wherein forming the third capacitor structure comprises:
forming a third conductive layer in the first dielectric structure; and
removing at least one portion of the third conductive layer to form a first conductive element and a second conductive element of the third capacitor structure, wherein a portion of the first dielectric structure separates the first conductive element of the third capacitor structure and the second conductive element of the third capacitor structure.
